(19) United States
(12) Patent Application Publication
(10) Pub. No.: US 2025/0031403 A1
(43) Pub. Date: Jan. 23, 2025

(54) CONTACT PLUG STRUCTURES OF SEMICONDUCTOR DEVICE AND METHODS OF FORMING SAME

(71) Applicant: Taiwan Semiconductor Manufacturing Co., Ltd., Hsinchu (TW)

(72) Inventors: Wei-Hao Wu, Hsinchu (TW); Kuan Yu Chen, Tainan City (TW)

(21) Appl. No.: 18/355,258

(22) Filed: Jul. 19, 2023

(51) Int. Cl. H01L 29/417; H01L 21/8238; H01L 27/092; H01L 29/66; H01L 29/78

(52) U.S. Cl. CPC H01L 29/41791; H01L 21/823814; H01L 21/823821; H01L 27/0924; H01L 29/66545; H01L 29/66795; H01L 29/7851

(57) ABSTRACT

A method includes forming an epitaxial source/drain region in a substrate; forming a first inter-layer dielectric over the epitaxial source/drain region; forming a gate stack over the substrate and adjacent to the first inter-layer dielectric; forming a gate mask over the gate stack; forming a source/drain plug through the first inter-layer dielectric and electrically connected to the epitaxial source/drain region; depositing a dielectric layer over the gate mask and the first inter-layer dielectric, the dielectric layer having a different etch selectivity than the gate mask; forming a second inter-layer dielectric over the dielectric layer; etching an opening through the second inter-layer dielectric and the dielectric layer, the opening exposing the source/drain plug and the gate mask; and forming a conductive feature in the opening, the conductive feature being electrically connected to the source/drain plug.

### BACKGROUND

Semiconductor devices are used in a variety of electronic applications, such as, for example, personal computers, cell phones, digital cameras, and other electronic equipment. Semiconductor devices are typically fabricated by sequentially depositing insulating or dielectric layers, conductive layers, and semiconductor layers of material over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. However, as the minimum features sizes are reduced, additional challenges arise that may be addressed.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates an example of a FinFET in a three-dimensional view in accordance with some embodiments.

FIGS. 2, 3, 4, 5, 6, 7, 8A, 8B, 9A, 9B, 10A, 10B, 10C, 10D, 11A, 11B, 12A, 12B, 13A, 13B, 14A, 14B, 14C, 15A, 15B, 16A, 16B, 17A, 17B, 18A, 18B, 19A, 19B, 20A, 20B, 21A, 21B, 22A, 22B, 23A, 23B, 24A, 24B, 25A, 25B, 25C, 25D, 25E, 25F, 26A, 26B, 26C, 26D, 26E, 26F, 27A, 27B, 27C, 27D, 27E, and 27F are cross-sectional views of intermediate stages in the manufacturing of FinFET devices in accordance with some embodiments.

FIGS. 25G and 26G are plan view schematics of intermediate stages in the manufacturing of FinFET devices in accordance with some embodiments.

FIGS. 26H and 26I are diagrams of various components in intermediate stages in the manufacturing of FinFET devices in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Embodiments are described in a particular context, an integrated circuit die including fin field-effect transistors (finFETs). Various embodiments may be applied, however, to dies including other types of transistors (e.g., nano-FETs, such as nanowire FETs, nanosheet FETs, or the like), planar transistors, or the like) in lieu of or in combination with the finFETs. In addition, various embodiments presented herein are discussed in the context of a fin field effect transistor (FinFET) device formed using a gate-last process. In other embodiments, a gate-first process may be used.

Embodiments herein provide formation of contact plug structures of a semiconductor device and methods of forming the same. In accordance with some embodiments, an etch stop layer comprising a dielectric material is formed over gate stacks of a semiconductor device. The dielectric material is selected to have a high etch selectivity with gate masks overlying the gate stacks. One or more dielectric layers may be formed over the etch stop layer. Openings are etched in the overlying dielectric layers, and conductive features are formed over and electrically connected to the source/drain contact plugs. The conductive features may be formed with shapes that improve electrical connection and lower electrical resistance with the respective source/drain contact plugs. The high selectivity of the etch stop layer benefits forming the openings (and conductive features therein), such that the gate masks remain unetched and a leakage between the gate stacks and the conductive features (as well as the source/drain contact plugs) is reduced. The various embodiments discussed herein allow for a variety of shapes for the conductive features (including extending directly above some of the gate stacks) while improving electrical performance of a semiconductor device.

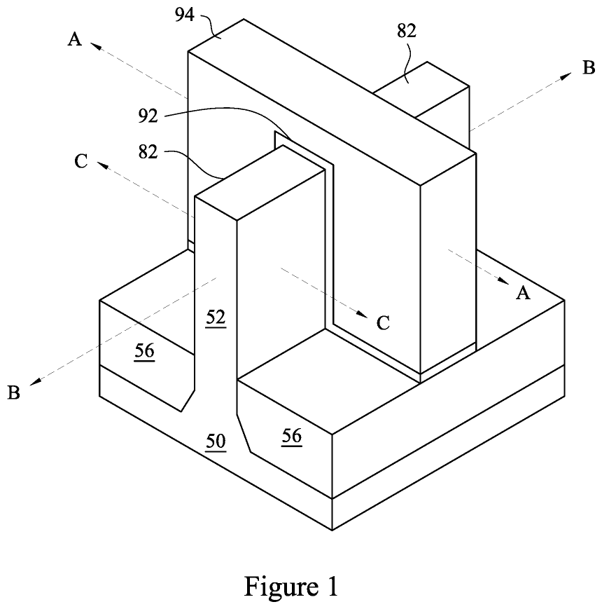

FIG. 1 illustrates an example of a FinFET in a three-dimensional view in accordance with some embodiments. The FinFET comprises a fin 52 on a substrate 50 (e.g., a semiconductor substrate). Isolation regions 56 are disposed in the substrate 50, and the fin 52 protrudes above and from between neighboring isolation regions 56. Although the isolation regions 56 are described/illustrated as being separate from the substrate 50, as used herein the term “substrate” may be used to refer to just the semiconductor substrate or a semiconductor substrate inclusive of isolation regions. Additionally, although the fin 52 is illustrated as a single, continuous material as the substrate 50, the fin 52 and/or the substrate 50 may comprise a single material or a plurality of materials. In this context, the fin 52 refers to the portion extending between the neighboring isolation regions 56.

A gate dielectric layer 92 is along sidewalls and over a top surface of the fin 52, and a gate electrode 94 is over the gate dielectric layer 92. Source/drain regions 82 are disposed in opposite sides of the fin 52 with respect to the gate dielectric layer 92 and the gate electrode 94. FIG. 1 further illustrates reference cross-sections that are used in later figures. Cross-section A-A is along a longitudinal axis of the gate electrode 94 and in a direction, for example, perpendicular to a direction of a current flow between the source/drain regions 82 of the FinFET. Cross-section B-B is perpendicular to cross-section A-A and is along a longitudinal axis of the fin 52 and in a direction of, for example, the current flow between the source/drain regions 82 of the FinFET. Cross-section C-C is parallel to cross-section A-A and extends through the source/drain region 82 of the FinFET. Subsequent figures refer to these reference cross-sections for clarity.

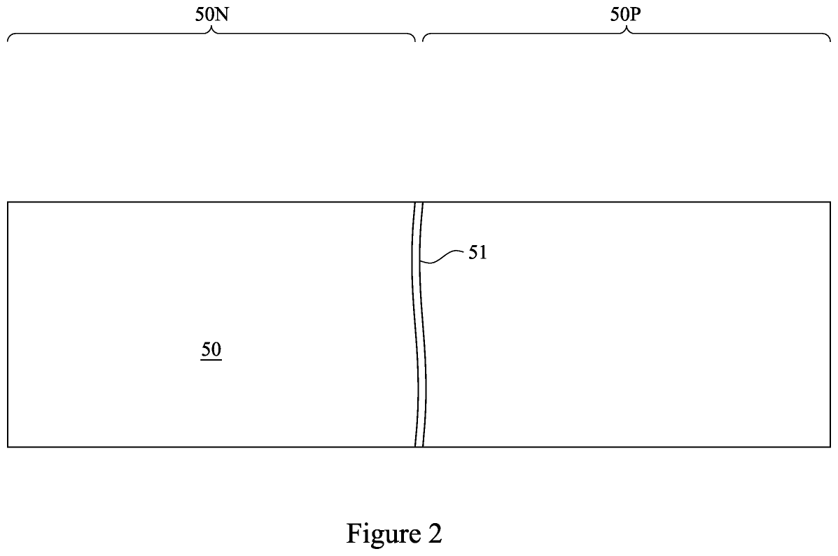

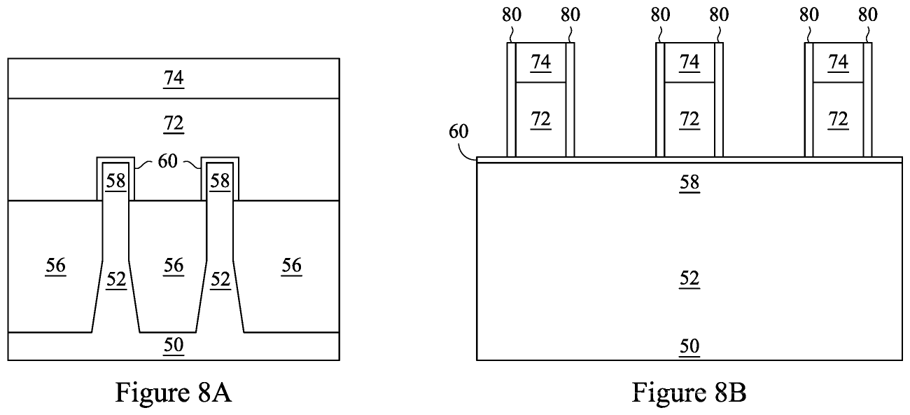

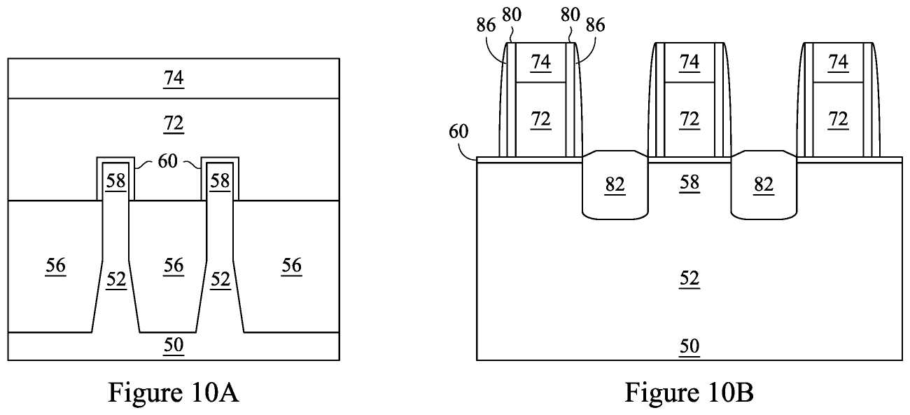

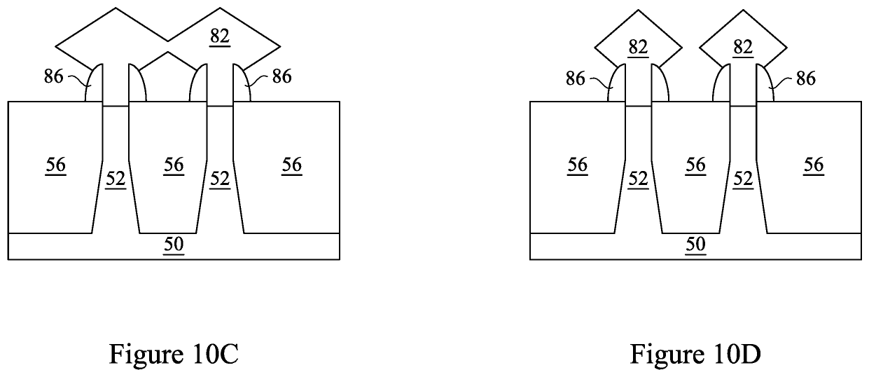

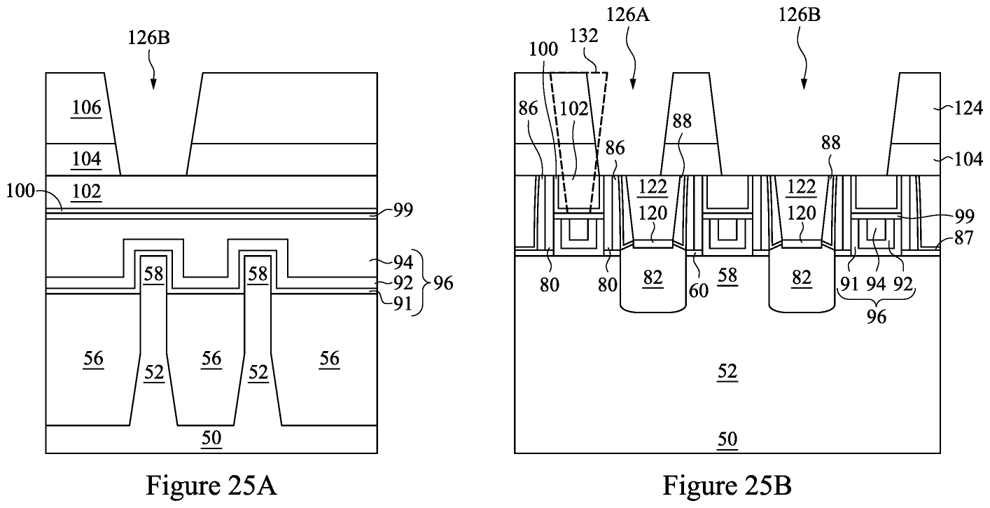

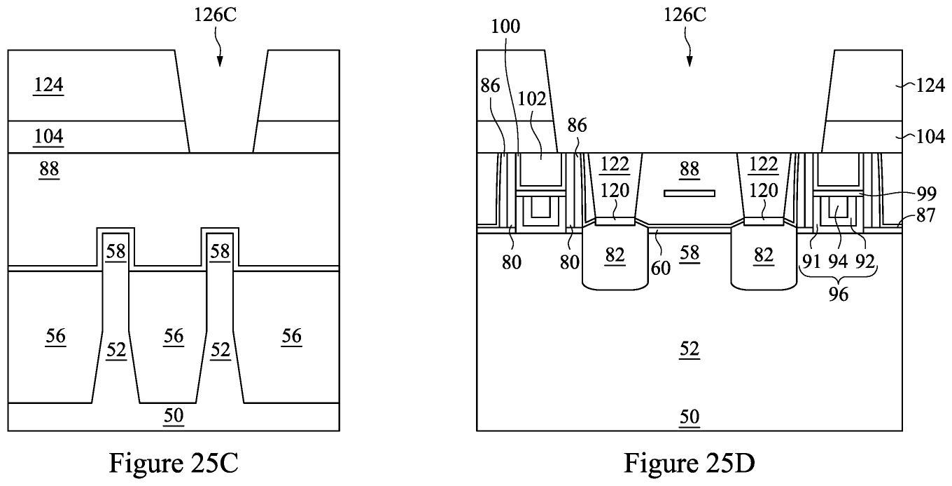

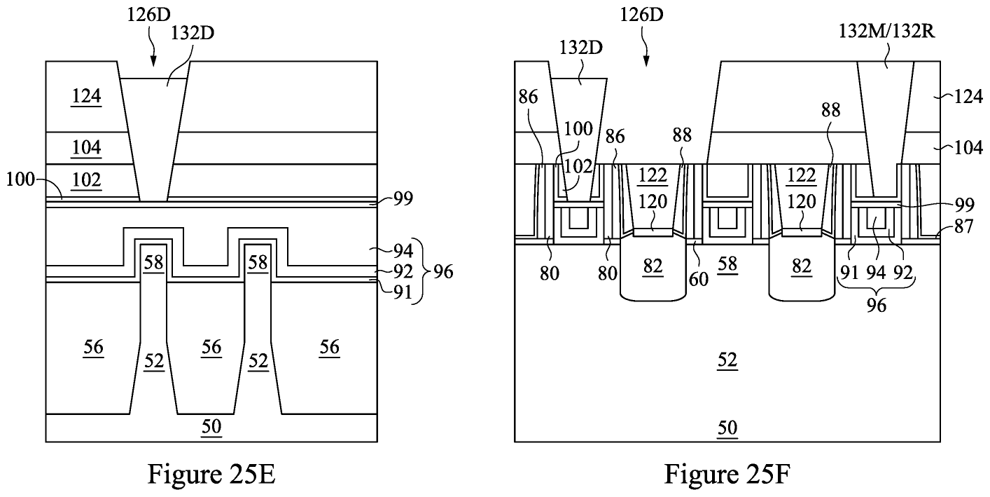

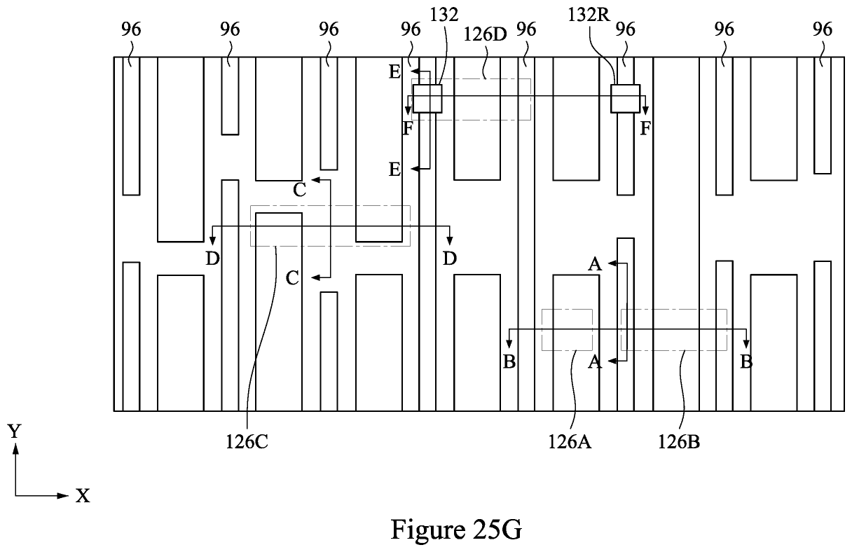

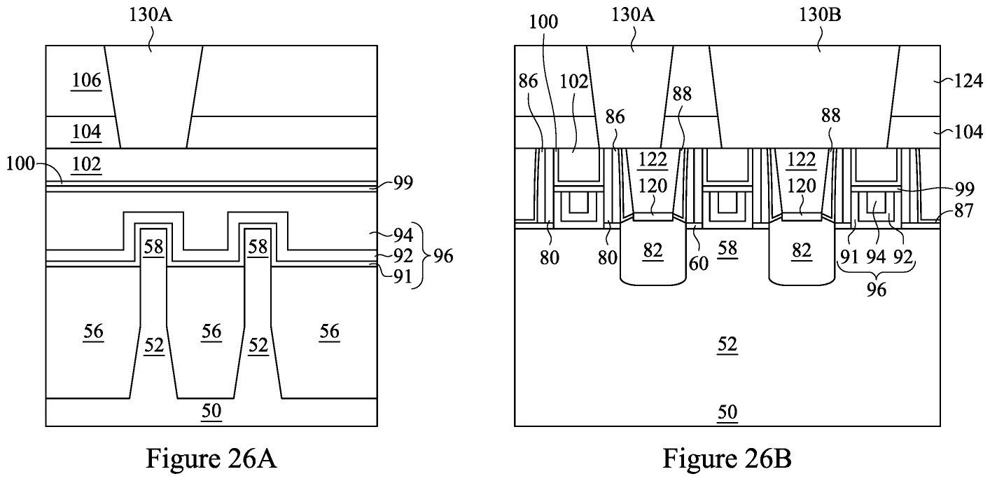

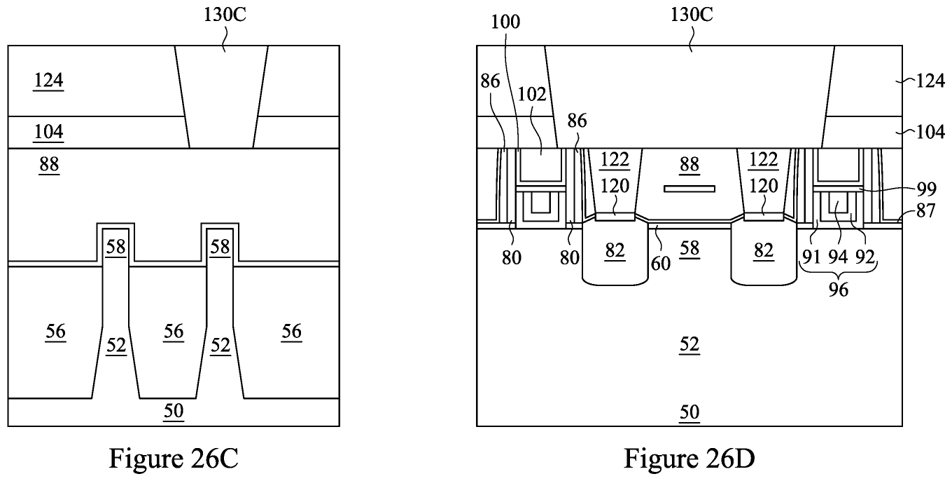

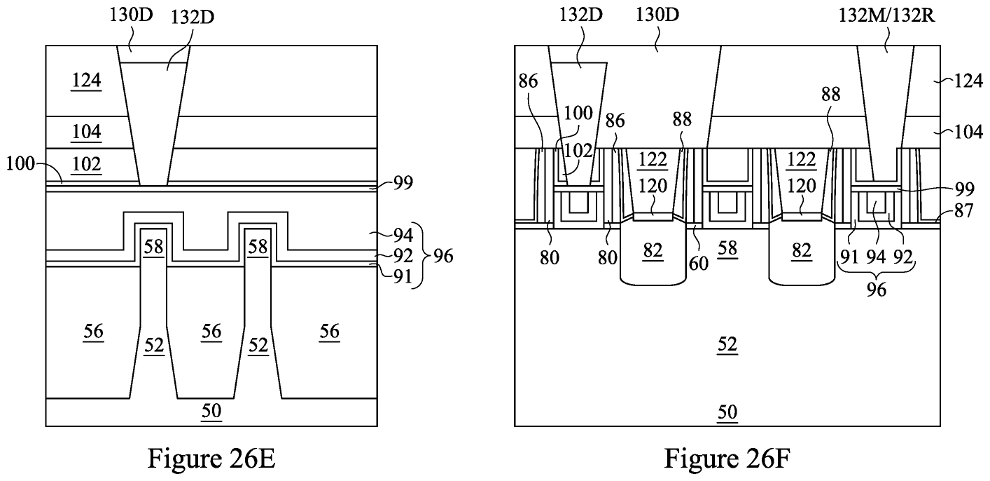

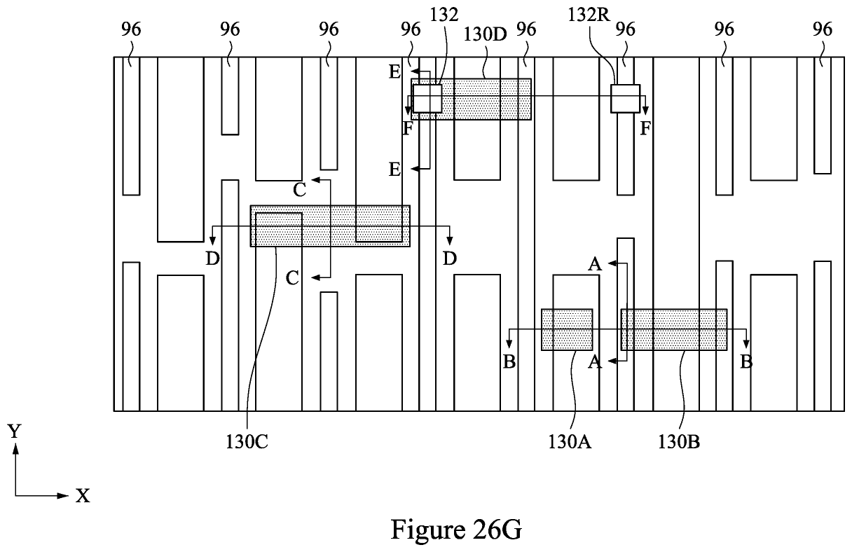

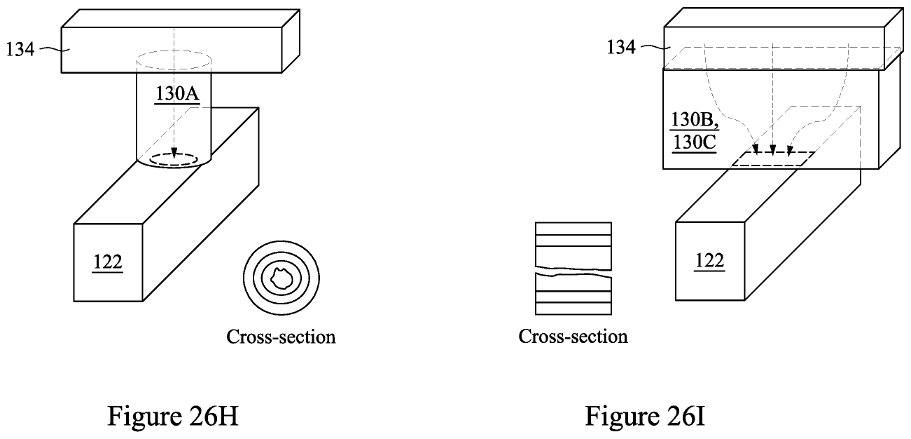

FIGS. 2-27F are cross-sectional views, plan view, and diagrams of intermediate stages in the manufacturing of FinFET devices in accordance with some embodiments. FIGS. 2 through 7 illustrate cross-sectional views along the reference cross-section A-A illustrated in FIG. 1, except for multiple fins/FinFETs. FIGS. 8A-24A, 25A, 25C, 25E, 26A, 26C, 26E, 27A, 27C, and 27E are illustrated along the reference cross-section A-A illustrated in FIG. 1, except for multiple fins/FinFETs. FIGS. 8B-24B, 14C, 25B, 25D, 25F, 26B, 26D, 26F, 27B, 27D, and 27F are illustrated along the reference cross-section B-B illustrated in FIG. 1, except for multiple gates. FIGS. 10C and 10D are illustrated along the reference cross-section C-C illustrated in FIG. 1, except for multiple fins/FinFETs. FIGS. 25G and 26G illustrate top-down schematics (e.g., plan views). FIGS. 26H and 26I are diagrams of various components formed around and electrically connected to the FinFET devices in accordance with some embodiments.

In FIG. 2, a substrate 50 is provided. The substrate 50 may be a semiconductor substrate, such as a bulk semiconductor, a semiconductor-on-insulator (SOI) substrate, or the like, which may be doped (e.g., with a p-type or an n-type dopant) or undoped. The substrate 50 may be a wafer, such as a silicon wafer. Generally, an SOI substrate is a layer of a semiconductor material formed on an insulator layer. The insulator layer may be, for example, a buried oxide (BOX) layer, a silicon oxide layer, or the like. The insulator layer is provided on a substrate, typically a silicon or glass substrate. Other substrates, such as a multi-layered or gradient substrate may also be used. In some embodiments, the semiconductor material of the substrate 50 may include silicon; germanium; a compound semiconductor including silicon carbide, gallium arsenic, gallium phosphide, indium phosphide, indium arsenide, and/or indium antimonide; an alloy semiconductor including SiGe, GaAsP, AlInAs, AlGaAs, GaInAs, GaInP, and/or GaInAsP; or combinations thereof.

The substrate 50 has a region 50N and a region 50P. The region 50N can be for forming n-type devices, such as NMOS transistors, e.g., n-type FinFETs. The region 50P can be for forming p-type devices, such as PMOS transistors, e.g., p-type FinFETs. The region 50N may be physically separated from the region 50P (as illustrated by a divider 51), and any number of device features (e.g., other active devices, doped regions, isolation structures, etc.) may be disposed between the region 50N and the region 50P.

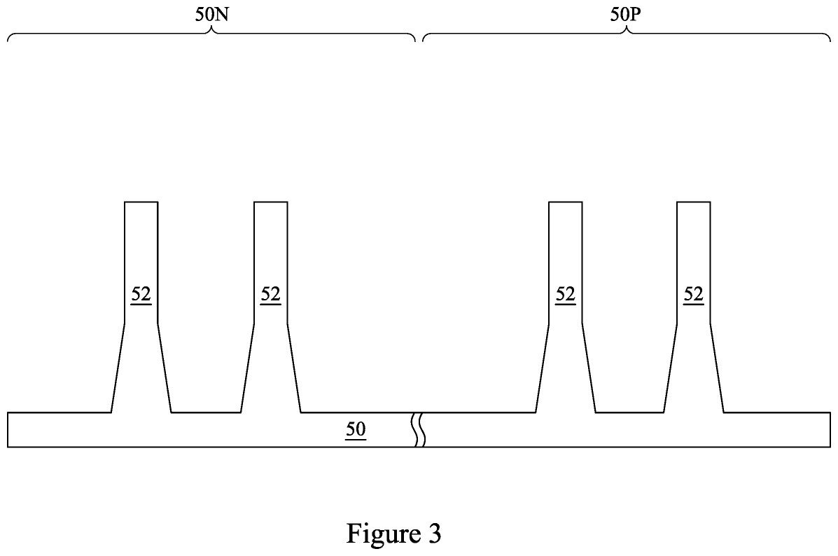

In FIG. 3, fins 52 are formed in the substrate 50. The fins 52 are semiconductor strips. In some embodiments, the fins 52 may be formed in the substrate 50 by etching trenches in the substrate 50. The etching may be any acceptable etch process, such as a reactive ion etch (RIE), neutral beam etch (NBE), a combination thereof, or the like. The etch process may be anisotropic.

The fins 52 may be formed by any suitable method. For example, the fins 52 may be formed using one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over the substrate 50 and patterned using a photolithography process. Spacers are formed alongside the patterned sacrificial layer using a self-aligned process. The sacrificial layer is then removed, and the remaining spacers may then be used as a mask to form the fins 52.

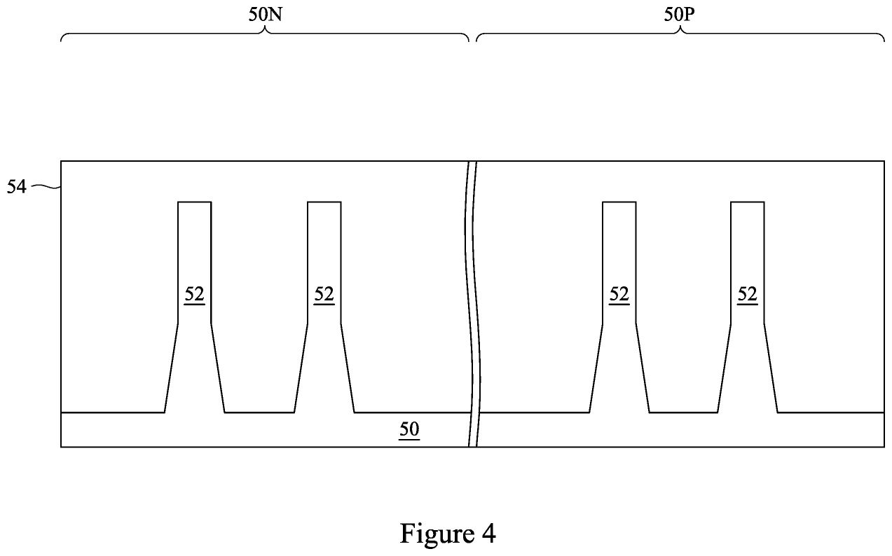

In FIG. 4, an insulation material 54 is formed over the substrate 50 and between neighboring fins 52. The insulation material 54 may be an oxide, such as silicon oxide, a nitride, a combination thereof, or the like, and may be formed by a high density plasma chemical vapor deposition (HDP-CVD), a flowable CVD (FCVD) (e.g., a CVD-based material deposition in a remote plasma system and post curing to make it convert to another material, such as an oxide), a combination thereof, or the like. Other insulation materials formed by any acceptable process may be used. In the illustrated embodiment, the insulation material 54 is silicon oxide formed by a FCVD process. An anneal process may be performed once the insulation material is formed. In an embodiment, the insulation material 54 is formed such that excess insulation material 54 covers the fins 52. Although the insulation material 54 is illustrated as a single layer, some embodiments may utilize multiple layers. For example, in some embodiments, a liner (not shown) may first be formed along surfaces of the substrate 50 and the fins 52. Thereafter, a fill material, such as those discussed above may be formed over the liner.

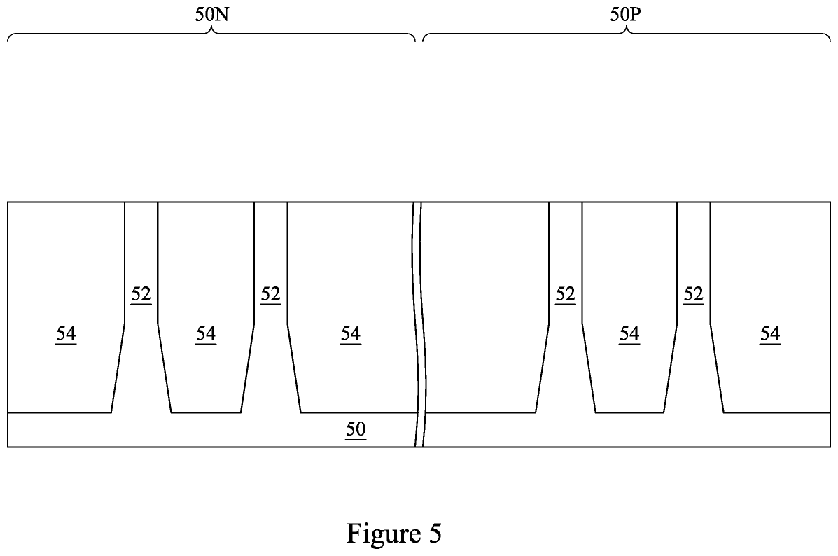

In FIG. 5, a removal process is applied to the insulation material 54 to remove excess portions of the insulation material 54 over the fins 52. In some embodiments, a planarization process, such as a chemical mechanical polish (CMP) process, an etch back process, a combination thereof, or the like, may be utilized. The planarization process exposes the fins 52, such that top surfaces of the fins 52 and the top surface of the insulation material 54 are substantially coplanar or level (within process variations of the planarization process) after the planarization process is completed.

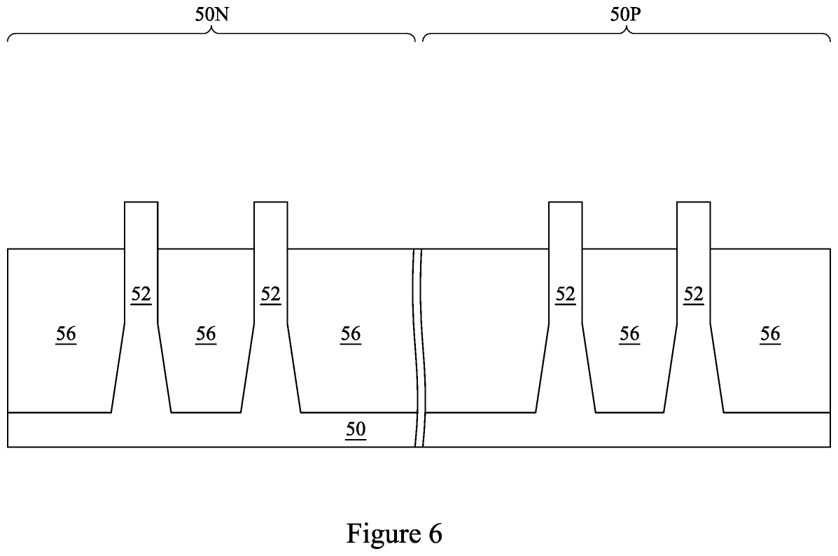

In FIG. 6, the insulation material 54 (see FIG. 5) is recessed to form shallow trench isolation (STI) regions 56. The insulation material 54 is recessed such that upper portions of fins 52 in the regions 50N and 50P protrude from between neighboring STI regions 56. Further, the top surfaces of the STI regions 56 may have a flat surface as illustrated, a convex surface, a concave surface (such as dishing), or a combination thereof. The top surfaces of the STI regions 56 may be formed flat, convex, and/or concave by an appropriate etch. The STI regions 56 may be recessed using an acceptable etching process, such as one that is selective to the material of the insulation material 54 (e.g., etches the material of the insulation material 54 at a faster rate than the material of the fins 52). For example, a chemical oxide removal with a suitable etch process using, for example, dilute hydrofluoric (dHF) acid may be used.

The process described with respect to FIGS. 2 through 6 is just one example of how the fins 52 may be formed. In some embodiments, the fins may be formed by an epitaxial growth process. For example, a dielectric layer can be formed over a top surface of the substrate 50, and trenches can be etched through the dielectric layer to expose the underlying substrate 50. Homoepitaxial structures can be epitaxially grown in the trenches, and the dielectric layer can be recessed such that the homoepitaxial structures protrude from the dielectric layer to form fins. Additionally, in some embodiments, heteroepitaxial structures can be used for the fins. For example, the fins 52 in FIG. 5 can be recessed, and a material different from the fins 52 may be epitaxially grown over the recessed fins 52. In such embodiments, the fins comprise the recessed material as well as the epitaxially grown material disposed over the recessed material. In an even further embodiment, a dielectric layer can be formed over a top surface of the substrate 50, and trenches can be etched through the dielectric layer. Heteroepitaxial structures can then be epitaxially grown in the trenches using a material different from the substrate 50, and the dielectric layer can be recessed such that the heteroepitaxial structures protrude from the dielectric layer to form the fins. In some embodiments where homoepitaxial or heteroepitaxial structures are epitaxially grown, the epitaxially grown materials may be in situ doped during growth, which may obviate prior and subsequent implantations, although in situ and implantation doping may be used together.

Still further, it may be advantageous to epitaxially grow a material in the region 50N different from a material in the region 50P. In various embodiments, upper portions of the fins 52 may be formed from silicon germanium (SiₓGe₁₋ₓ, where x can be in the range of 0 to 1), silicon carbide, pure or substantially pure germanium, a III-V compound semiconductor, a II-VI compound semiconductor, or the like. For example, the available materials for forming III-V compound semiconductor include, but are not limited to, InAs, AlAs, GaAs, InP, GaN, InGaAs, InAlAs, GaSb, AlSb, AlP, GaP, and the like.

Further in FIG. 6, appropriate wells (not shown) may be formed in the fins 52 and/or the substrate 50. In some embodiments, a P well may be formed in the region 50N, and an N well may be formed in the region 50P. In some embodiments, a P well or an N well are formed in both the region 50N and the region 50P. In the embodiments with different well types, the different implant steps for the region 50N and the region 50P may be achieved using a photoresist or other masks (not shown). For example, a first photoresist may be formed over the fins 52 and the STI regions 56 in both the region 50N and the region 50P. The first photoresist is patterned to expose the region 50P of the substrate 50. The first photoresist can be formed by using a spin-on technique and can be patterned using acceptable photolithography techniques. Once the first photoresist is patterned, an n-type impurity implantation is performed in the region 50P, while the remaining portion of the first photoresist acts as a mask to substantially prevent n-type impurities from being implanted into the region 50N. The n-type impurities may be phosphorus, arsenic, antimony, or the like, implanted in the region 50P to a dose of equal to or less than 10¹⁵ cm⁻², such as between about 10¹² cm⁻² and about 10¹⁵ cm⁻². In some embodiments, the n-type impurities may be implanted at an implantation energy of about 1 keV to about 10 keV. After the implantation, the first photoresist is removed, such as by an acceptable ashing process followed by a wet clean process.

Following the implantation of the region 50P, a second photoresist is formed over the fins 52 and the STI regions 56 in both the region 50P and the region 50N. The second photoresist is patterned to expose the region 50N of the substrate 50. The second photoresist can be formed by using a spin-on technique and can be patterned using acceptable photolithography techniques. Once the second photoresist is patterned, a p-type impurity implantation may be performed in the region 50N, while the remaining portion of the second photoresist acts as a mask to substantially prevent p-type impurities from being implanted into the region 50P. The p-type impurities may be boron, BF₂, indium, or the like, implanted in the region 50N to a dose of equal to or less than 10¹⁵ cm⁻², such as between about 10¹² cm⁻² and about 10¹⁵ cm⁻². In some embodiments, the p-type impurities may be implanted at an implantation energy of about 1 keV to about 10 keV. After the implantation, the second photoresist may be removed, such as by an acceptable ashing process followed by a wet clean process.

After performing the implantations of the region 50N and the region 50P, an anneal process may be performed to activate the p-type and/or n-type impurities that were implanted. In some embodiments, the grown materials of epitaxial fins may be in situ doped during growth, which may obviate the implantations, although in situ doping and implantation doping may be used together.

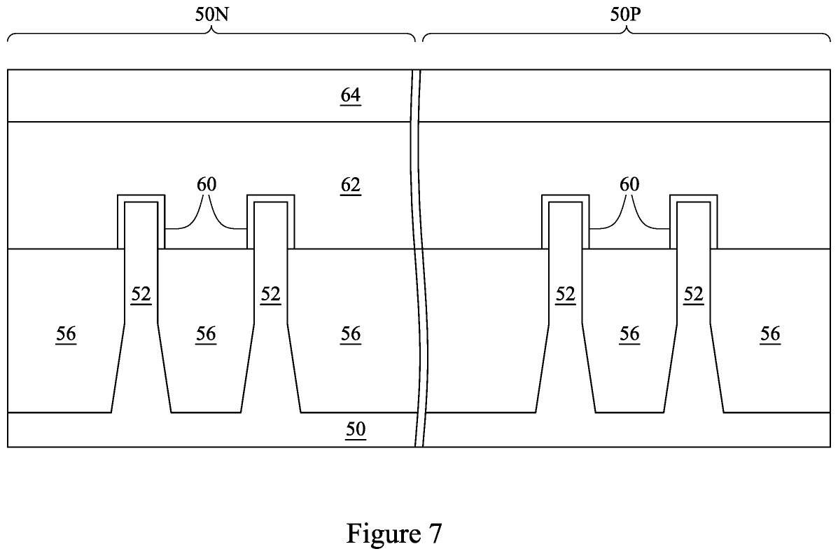

In FIG. 7, a dummy dielectric layer 60 is formed on the fins 52. The dummy dielectric layer 60 may be, for example, silicon oxide, silicon nitride, a combination thereof, or the like, and may be deposited or thermally grown according to acceptable techniques. A dummy gate layer 62 is formed over the dummy dielectric layer 60, and a mask layer 64 is formed over the dummy gate layer 62. The dummy gate layer 62 may be deposited over the dummy dielectric layer 60 and then planarized using, for example, a CMP process. The mask layer 64 may be deposited over the dummy gate layer 62. The dummy gate layer 62 may be a conductive material and may be selected from a group including amorphous silicon, polycrystalline-silicon (polysilicon), poly-crystalline silicon-germanium (poly-SiGe), metallic nitrides, metallic silicides, metallic oxides, and metals. The dummy gate layer 62 may be deposited by physical vapor deposition (PVD), CVD, sputter deposition, or other techniques known and used in the art for depositing conductive materials. The dummy gate layer 62 may be made of other materials that have a high etching selectivity than materials of the STI regions 56. The mask layer 64 may include, for example, one or more layers of silicon oxide, SiN, SiON, a combination thereof, or the like. In some embodiments, the mask layer 64 may comprise a layer of silicon nitride and a layer of silicon oxide over the layer of silicon nitride. In some embodiments, a single dummy gate layer 62 and a single mask layer 64 are formed across the region 50N and the region 50P. It is noted that the dummy dielectric layer 60 is shown covering only the fins 52 for illustrative purposes only. In some embodiments, the dummy dielectric layer 60 may be deposited such that the dummy dielectric layer 60 covers the STI regions 56, extending between the dummy gate layer 62 and the STI regions 56.

FIGS. 8A-26F illustrate various additional steps in the manufacturing of a FinFET device in accordance with some embodiments. The figures illustrate features in either of the region 50N and the region 50P. For example, the illustrated structures may be applicable to both the region 50N and the region 50P. Differences (if any) in the structures of the region 50N and the region 50P are described in the text accompanying each figure.

In FIGS. 8A and 8B, the mask layer 64 (see FIG. 7) may be patterned using acceptable photolithography and etching techniques to form masks 74. In some embodiments, the etching techniques may include one or more anisotropic etch processes, such as a reactive ion etch (RIE), neutral beam etch (NBE), a combination thereof, or the like. Subsequently, the pattern of the masks 74 may be transferred to the dummy gate layer 62 (see FIG. 7) to form dummy gates 72. In some embodiments, the pattern of the masks 74 may also be transferred to the dummy dielectric layer 60 by an acceptable etching technique. The dummy gates 72 cover channel regions 58 of the fins 52. The pattern of the masks 74 may be used to physically separate each of the dummy gates 72 from adjacent dummy gates. The dummy gates 72 may also have a lengthwise direction substantially perpendicular to the lengthwise direction of respective one of the fins 52. As described below in greater detail, the dummy gates 72 are sacrificial gates and are subsequently replaced by replacement gates. Accordingly, dummy gates 72 may also be referred to as sacrificial gates. In other embodiments, some of the dummy gates 72 are not replaced and remain in the final structure of the embodiment FinFET devices.

Further in FIGS. 8A and 8B, gate seal spacers 80 may be formed on exposed surfaces of the dummy gates 72, the masks 74, and/or the fins 52. A thermal oxidation or a deposition followed by an anisotropic etch may form the gate seal spacers 80. The gate seal spacers 80 may comprise silicon oxide, silicon nitride, SiCN, SiOC, SiOCN, a combination thereof, or the like. After the formation of the gate seal spacers 80, implants for lightly doped source/drain (LDD) regions (not explicitly illustrated) may be performed. In the embodiments with different device types, similar to the implants discussed above in FIG. 6, a mask, such as a photoresist, may be formed over the region 50N, while exposing the region 50P, and appropriate type (e.g., p-type) impurities may be implanted into the exposed fins 52 in the region 50P. The mask may then be removed. Subsequently, a mask, such as a photoresist, may be formed over the region 50P, while exposing the region 50N, and appropriate type impurities (e.g., n-type) may be implanted into the exposed fins 52 in the region 50N. The mask may then be removed. The n-type impurities may be the any of the n-type impurities previously discussed, and the p-type impurities may be the any of the p-type impurities previously discussed. The lightly doped source/drain regions may have a dose of impurities of from about 10¹² cm⁻² to about 1016 cm⁻². In some embodiments, the suitable impurities may be implanted at an implantation energy of about 1 keV to about 10 keV. An anneal may be used to activate the implanted impurities.

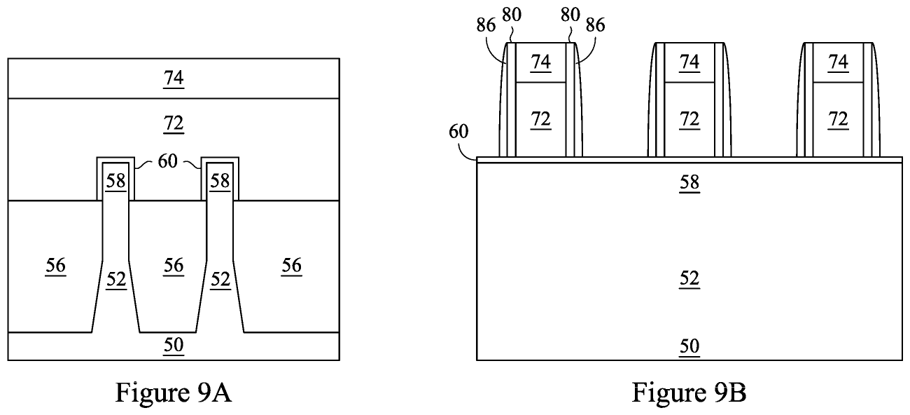

In FIGS. 9A and 9B, gate spacers 86 are formed on the gate seal spacers 80 along sidewalls of the dummy gates 72 and the masks 74. The gate spacers 86 may be formed by conformally depositing an insulating material and subsequently anisotropically etching the insulating material. The insulating material of the gate spacers 86 may comprise silicon oxide, silicon nitride, SiCN, SiOC, SiOCN, a combination thereof, or the like. In some embodiments, the gate spacers 86 may comprise a plurality of layers (not shown), such that the layers comprise different materials.

It is noted that the above disclosure generally describes a process of forming spacers and LDD regions. Other processes and sequences may be used. For example, fewer or additional spacers may be utilized, different sequence of steps may be utilized (e.g., the gate seal spacers 80 may not be etched prior to forming the gate spacers 86, yielding “L-shaped” gate seal spacers, spacers may be formed and removed, and/or the like). Furthermore, the n-type and p-type devices may be formed using a different structures and steps. For example, LDD regions for n-type devices may be formed prior to forming the gate seal spacers 80 while the LDD regions for p-type devices may be formed after forming the gate seal spacers 80.

In FIGS. 10A and 10B, epitaxial source/drain regions 82 are formed in the fins 52 to exert stress in the respective channel regions 58, thereby improving device performance. The epitaxial source/drain regions 82 are formed in the fins 52 such that each dummy gate 72 is disposed between respective neighboring pairs of the epitaxial source/drain regions 82. In some embodiments, the epitaxial source/drain regions 82 may extend into, and may also penetrate through, the fins 52. In some embodiments, the gate spacers 86 are used to separate the epitaxial source/drain regions 82 from the dummy gates 72 by an appropriate lateral distance so that the epitaxial source/drain regions 82 do not short out subsequently formed gates of the embodiment FinFET devices.

The epitaxial source/drain regions 82 in the region 50N may be formed by masking the region 50P and etching source/drain regions of the fins 52 in the region 50N to form recesses in the fins 52. Then, the epitaxial source/drain regions 82 in the region 50N are epitaxially grown in the recesses. The epitaxial source/drain regions 82 may include any acceptable material, such as appropriate for n-type FinFETs. For example, if the fin 52 is silicon, the epitaxial source/drain regions 82 in the region 50N may include materials exerting a tensile strain in the channel region 58, such as silicon, SiC, SiCP, SiP, a combination thereof, or the like. The epitaxial source/drain regions 82 in the region 50N may have surfaces raised from respective surfaces of the fins 52 and may have facets.

The epitaxial source/drain regions 82 in the region 50P may be formed by masking the region 50N and etching source/drain regions of the fins 52 in the region 50P to form recesses in the fins 52. Then, the epitaxial source/drain regions 82 in the region 50P are epitaxially grown in the recesses. The epitaxial source/drain regions 82 may include any acceptable material, such as appropriate for p-type FinFETs. For example, if the fin 52 is silicon, the epitaxial source/drain regions 82 in the region 50P may comprise materials exerting a compressive strain in the channel region 58, such as SiGe, SiGeB, Ge, GeSn, a combination thereof, or the like. The epitaxial source/drain regions 82 in the region 50P may also have surfaces raised from respective surfaces of the fins 52 and may have facets.

The epitaxial source/drain regions 82 and/or the fins 52 may be implanted with dopants to form source/drain regions, similar to the process previously discussed for forming lightly-doped source/drain regions, followed by an anneal. The source/drain regions 82 may have an impurity concentration of between about 10¹⁹ cm⁻³ and about 10²¹ cm⁻³. The n-type and/or p-type impurities for the epitaxial source/drain regions 82 may be any of the impurities previously discussed. In some embodiments, the epitaxial source/drain regions 82 may be in situ doped during growth.

As a result of the epitaxy processes used to form the epitaxial source/drain regions 82 in the region 50N and the region 50P, upper surfaces of the epitaxial source/drain regions 82 have facets which expand laterally outward beyond sidewalls of the fins 52. In some embodiments, these facets cause adjacent epitaxial source/drain regions 82 of a same FinFET to merge as illustrated by FIG. 10C. In other embodiments, adjacent epitaxial source/drain regions 82 remain separated after the epitaxy process is completed as illustrated by FIG. 10D. In the embodiments illustrated in FIGS. 10C and 10D, the gate spacers 86 are formed covering a portion of the sidewalls of the fins 52 that extend above the STI regions 56 thereby blocking the epitaxial growth. In other embodiments, the spacer etch used to form the gate spacers 86 may be adjusted to remove the spacer material from the sidewalls of the fins 52 to allow the epitaxially grown region to extend to the surface of the STI region 56.

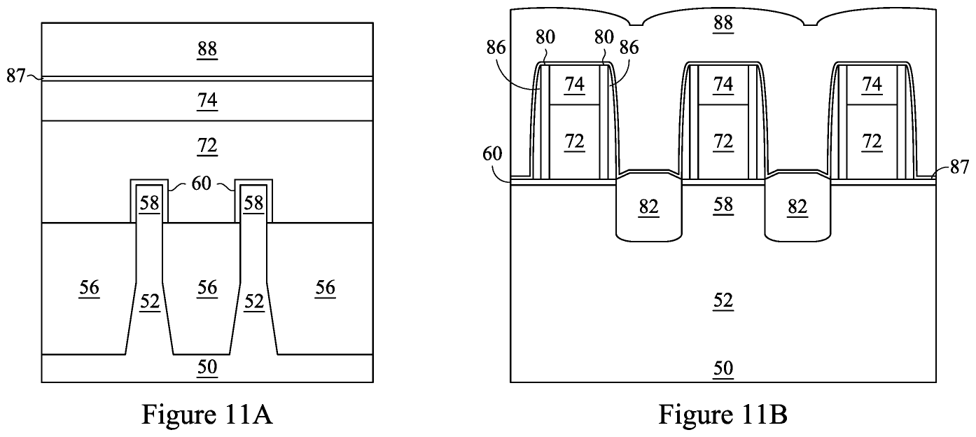

In FIGS. 11A and 11B, an ILD 88 is deposited over the structure illustrated in FIGS. 10A and 10B. The ILD 88 may be formed of a dielectric material, and may be deposited by any suitable method, such as CVD, plasma-enhanced CVD (PECVD), FCVD, a combination thereof, or the like. Dielectric materials may include Phospho-Silicate Glass (PSG), Boro-Silicate Glass (BSG), Boron-Doped Phospho-Silicate Glass (BPSG), undoped Silicate Glass (USG), a combination thereof, or the like. Other insulation materials formed by any acceptable process may be also used. In some embodiments, a contact etch stop layer (CESL) 87 is disposed between the ILD 88 and the epitaxial source/drain regions 82, the masks 74, and the gate spacers 86. The CESL 87 may comprise a dielectric material, such as, silicon nitride, silicon oxide, silicon oxynitride, a combination thereof, or the like, having a different etch rate than the material of the overlying ILD 88.

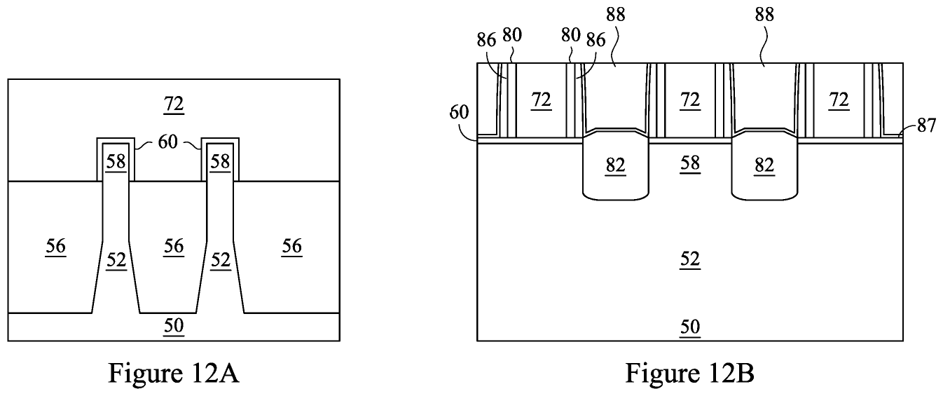

In FIGS. 12A and 12B, a planarization process, such as a CMP process, may be performed to level the top surface of the ILD 88 with the top surfaces of the dummy gates 72 or the masks 74 (see FIGS. 11A and 11B). The planarization process may also remove the masks 74 on the dummy gates 72, and portions of the gate seal spacers 80 and the gate spacers 86 along sidewalls of the masks 74. After the planarization process, top surfaces of the dummy gates 72, the gate seal spacers 80, the gate spacers 86, and the ILD 88 are substantially coplanar or level with each other within process variations of the planarization process. Accordingly, the top surfaces of the dummy gates 72 are exposed through the ILD 88. In some embodiments, the masks 74 may remain, in which case the planarization process levels the top surface of the ILD 88 with the top surfaces of the masks 74.

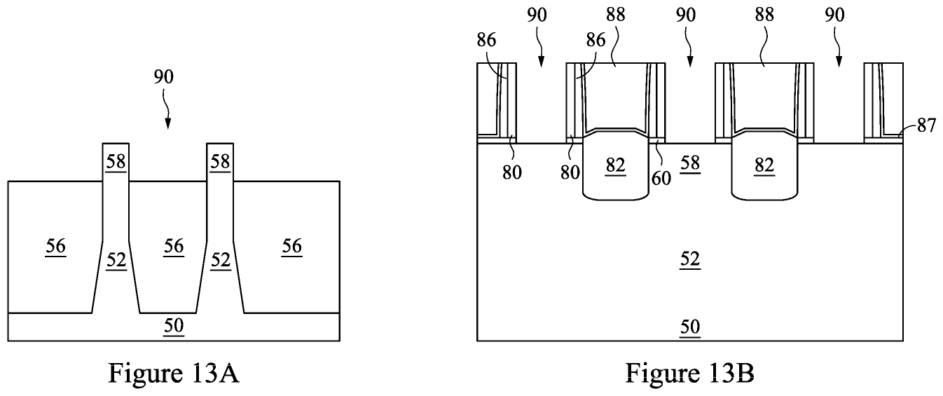

In FIGS. 13A and 13B, the dummy gates 72, and the masks 74, if present, are removed in an etching step(s), so that openings 90 are formed. In some embodiments, portions of the dummy dielectric layer 60 in the openings 90 may also be removed. In other embodiments, only the dummy gates 72 are removed and the dummy dielectric layer 60 remains and is exposed by the openings 90. In some embodiments, the dummy dielectric layer 60 is removed from the openings 90 in a first region of a die (e.g., a core logic region) and remains in openings 90 in a second region of the die (e.g., an input/output region). In some embodiments, the dummy gates 72 are removed by an anisotropic dry etch process. For example, the etching process may include a dry etch process using reaction gas(es) that selectively etch the dummy gates 72 without etching the ILD 88 or the gate spacers 86. Each opening 90 exposes a channel region 58 of a respective fin 52. Each channel region 58 is disposed between neighboring pairs of the epitaxial source/drain regions 82. During the removal, the dummy dielectric layer 60 may be used as an etch stop layer when the dummy gates 72 are etched. The dummy dielectric layer 60 may then be optionally removed after the removal of the dummy gates 72.

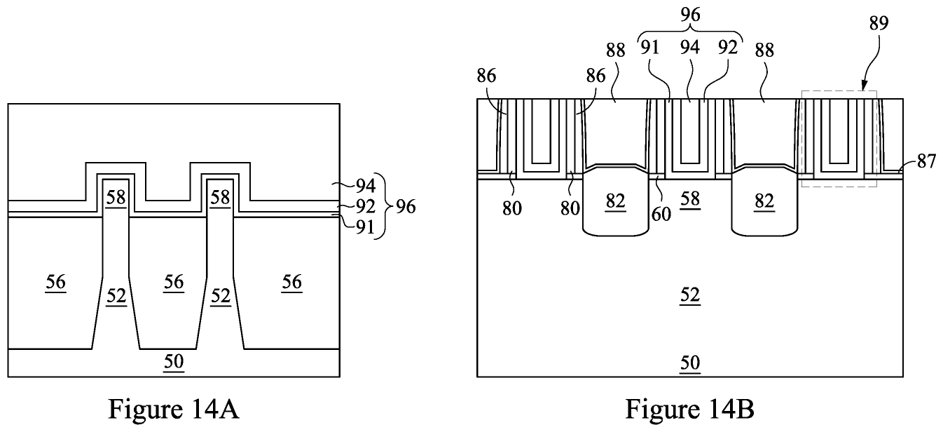

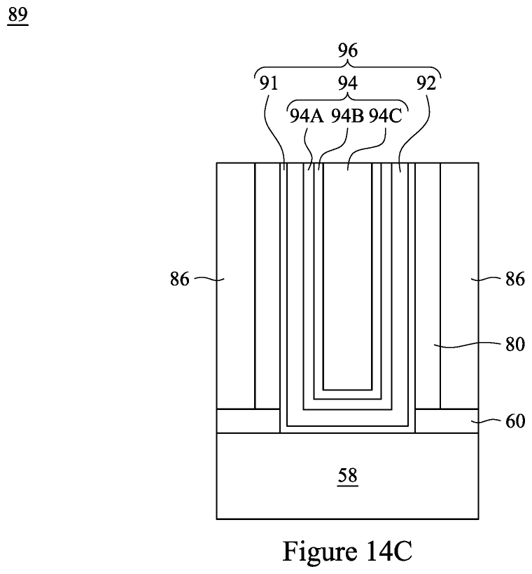

In FIGS. 14A and 14B, interfacial layers 91, gate dielectric layers 92 and gate electrodes 94 are formed in the openings 90 (see FIGS. 13A and 13B) to form gate stacks 96. The gate stacks 96 may be also referred to as replacement gate stacks. FIG. 14C illustrates a detailed view of a region 89 of FIG. 14B. In some embodiments, the interfacial layers 91 are formed in the openings 90 (see FIGS. 13A and 13B). The interfacial layers 91 may comprise silicon oxide and may be formed using a chemical deposition process, such as ALD, CVD, or the like, or using an oxidation process. In some embodiments where the interfacial layers 91 are formed using a deposition process, the interfacial layers 91 extend along exposed surfaces of the fins 52, the STI regions 56, and the gate seal spacers 80. In some embodiments where the interfacial layers 91 are formed using an oxidation process, the interfacial layers 91 extend along exposed surfaces of the fins 52, and do not extend along exposed surfaces of the STI regions 56 and the gate seal spacers 80. In some embodiments, the interfacial layers 91 have a thickness less than about 20 Å.

In some embodiments, the gate dielectric layers 92 are deposited in the openings 90 over the interfacial layers 91. The gate dielectric layers 92 may also be formed on the top surface of the ILD 88. In accordance with some embodiments, the gate dielectric layers 92 comprise silicon oxide, silicon nitride, or multilayers thereof. In some embodiments, the gate dielectric layers 92 include a high-k dielectric material, and in these embodiments, the gate dielectric layers 92 may have a k value greater than about 7.0, and may include a metal oxide or a silicate of hafnium, aluminum, zirconium, lanthanum, manganese, barium, titanium, lead, and combinations thereof. The formation methods of the gate dielectric layers 92 may include Molecular-Beam Deposition (MBD), ALD, PECVD, a combination thereof, or the like.

Further in FIGS. 14A and 14B, the gate electrodes 94 are deposited over the gate dielectric layers 92 and fill the remaining portions of the openings 90 (see FIGS. 13A and 13B). Although a single layer gate electrode 94 is illustrated in FIG. 14B, the gate electrode 94 may comprise any number of liner layers 94A, any number of work function tuning layers 94B, and a conductive fill layer 94C as illustrated by FIG. 14C. The liner layers 94A may include TIN, TiO, TaN, TaC, combinations thereof, multi-layers thereof, or the like, and may be formed using PVD, CVD, ALD, a combination thereof, or the like. In region 50N, the work function tuning layers 94B may include Ti, Ag, Al, TiAl, TiAIN, TiAIC, TaC, TaCN, TaSIN, TaAIC, Mn, Zr, combinations thereof, multi-layers thereof, or the like, and may be formed using PVD, CVD, ALD, a combination thereof, or the like. In region 50P, the work function tuning layers 94B may include TIN, WN, TaN, Ru, Co, combinations thereof, multi-layers thereof, or the like, and may be formed using PVD, CVD, ALD, a combination thereof, or the like. In some embodiments, the conductive fill layer 94C may comprise Co, Ru, Al, Ag, Au, W, Ni, Ti, Cu, Mn, Pd, Re, Ir, Pt, Zr, alloys thereof, combinations thereof, multi-layers thereof, or the like, and may be formed using PVD, CVD, ALD, plating, a combination thereof, or the like.

After the filling of the openings 90 (see FIGS. 13A and 13B), a planarization process, such as a CMP, may be performed to remove the excess portions of the gate dielectric layers 92, the gate electrodes 94, and/or the interfacial layers 91, which excess portions are over the top surface of the ILD 88. The remaining portions of the gate electrodes 94, the gate dielectric layers 92, and the interfacial layers 91 thus form the gate stacks 96 of the embodiment FinFET devices. The gate stacks 96 may extend along sidewalls of the channel regions 58 of the fins 52.

The formation of the gate dielectric layers 92 in the region 50N and the region 50P may occur simultaneously such that the gate dielectric layers 92 in each region are formed of the same materials. In other embodiments, the gate dielectric layers 92 in each region may be formed by distinct processes such that the gate dielectric layers 92 in different regions may be formed of different materials. The formation of the conductive fill layers 94C in the region 50N and the region 50P may occur simultaneously such that the conductive fill layers 94C in each region are formed of the same materials. In other embodiments, the conductive fill layers 94C in each region may be formed by distinct processes such that the conductive fill layers 94C in different regions may be formed of different materials. Various masking steps may be used to mask and expose appropriate regions when using distinct processes.

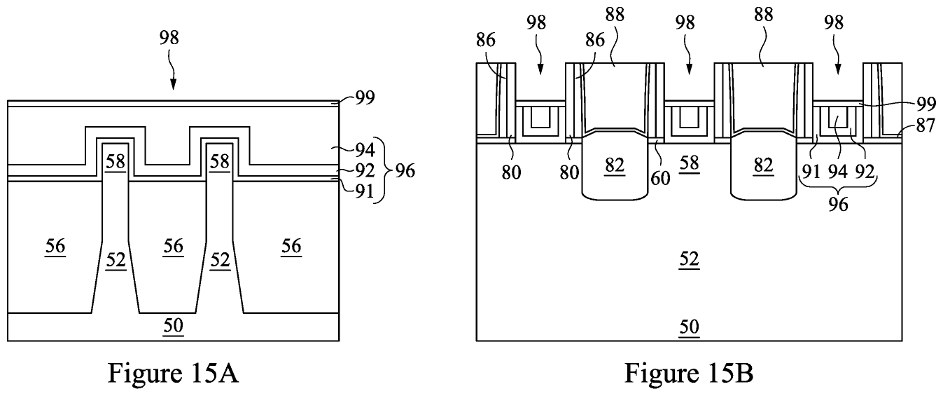

In FIGS. 15A and 15B, the gate stacks 96 are recessed below the top surface of the ILD 88 to form recesses 98. In some embodiments, the gate stacks 96 are recessed below the top surface of the ILD 88. In some embodiments, the gate stacks 96 are recessed to a depth of between about 10 nm and about 100 nm. In some embodiments, the gate stacks 96 are recessed using one or more etch processes. The one or more etch processes may comprise one or more dry etch processes, one or more wet etch processes, combinations thereof, or the like. The one or more etch processes may comprise anisotropic etch processes. In some embodiments, the one or more etch processes may be performed using etchants, such as Cl₂, HCl, F₂, HF, CF₄, SiCl₄, CHₓF_{y}, Ar, N₂, O₂, BCl₃, NF₃, a combination thereof, or the like.

Once the gate stacks 96 have been recessed, a gate contact layer 99 may be formed of tungsten, such as fluorine-free tungsten (FFW), which may be deposited by a selective deposition process, such as a selective CVD process. The gate contact layer 99 may be considered part of the gate stack 96. However, the gate contact layer 99 may include other conductive materials, such as ruthenium, cobalt, copper, molybdenum, nickel, combinations thereof, or the like and may be deposited using a suitable deposition process (e.g., ALD, CVD, PVD, or the like). As illustrated, the gate contact layer 99 may extend mostly or substantially between the gate seal spacers 80 and partially or fully surfaces of the gate dielectric layers 92 and the interfacial layers 91 (if exposed). The FFW may have a thickness of 8 nm to 10 nm, such as 8.5 nm.

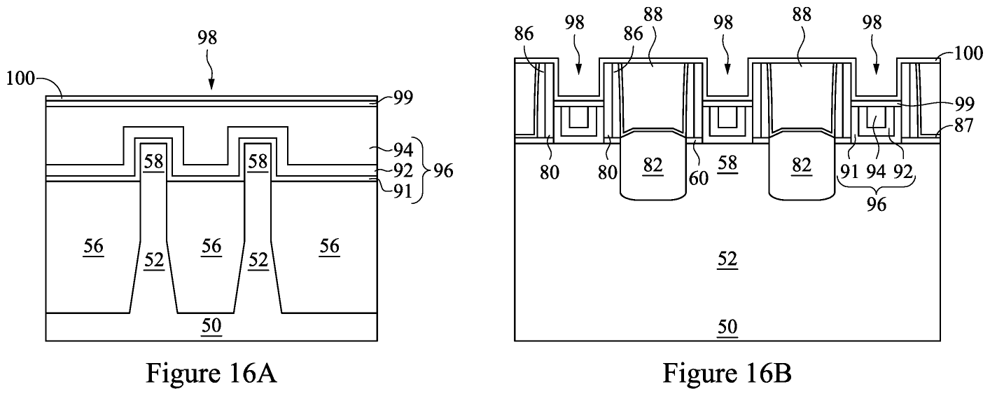

In FIGS. 16A and 16B, optionally, a metal dielectric liner 100 is deposited in the recesses 98 and over the recessed gate stacks 96 (e.g., along the gate contact layer 99), in accordance with some embodiments. The metal dielectric liner 100 will provide a self-alignment advantage during the subsequent formation of gate contact plugs. In some embodiments, the metal dielectric liner 100 comprises a metal oxide or silicate, wherein the metal may be hafnium, aluminum, zirconium, or the like. For example, the metal dielectric liner 100 may be hafnium oxide, aluminum oxide, or zirconium silicate. The metal dielectric liner 100 may be formed by ALD, MBD, PECVD, or any suitable method and may have a thickness ranging from 1 nm to 4 nm, such as ranging from 1 nm to 2 nm or ranging from 2 nm to 4 nm.

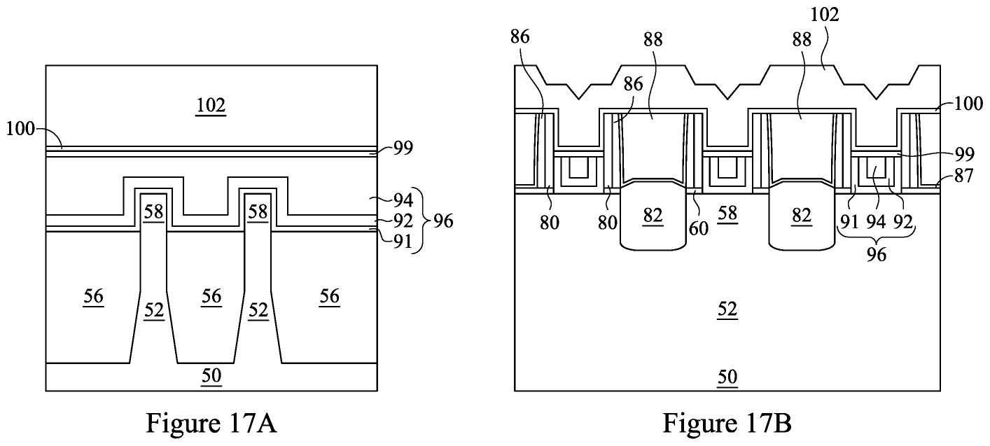

In FIGS. 17A and 17B, a dielectric layer 102 is formed in the recesses 98 (see FIGS. 15A and 15B) and over the ILD 88 and the metal dielectric liner 100 (if present). In some embodiments, the dielectric layer 102 overfills the recesses 98. In some embodiments, the dielectric layer 102 comprises materials that do not comprise oxygen. In some embodiments, the dielectric layer 102 comprises silicon nitride (SiN), silicon carbide (SiC), silicon carbonitride (SiCN), a combination thereof, or the like, and may be formed using ALD, CVD, a combination thereof, or the like. In accordance with some embodiments discussed herein, the dielectric layer comprises silicon nitride and may be referred to as a gate mask or a nitride mask.

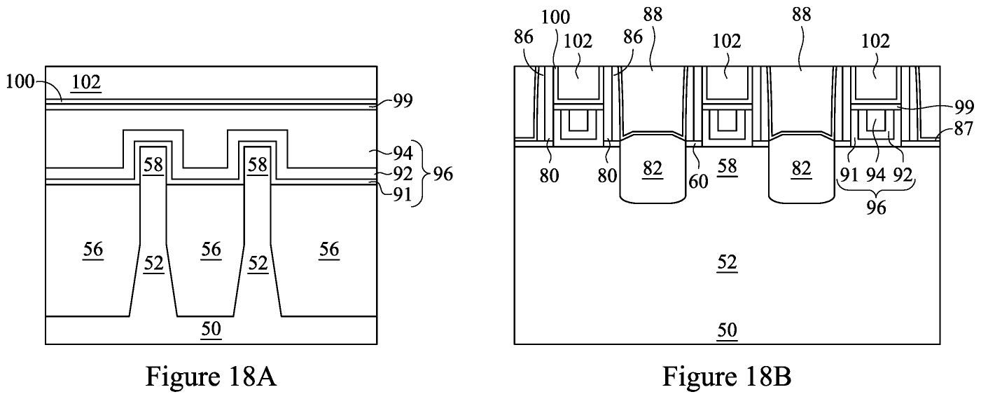

In FIGS. 18A and 18B, a planarization process is performed on the dielectric layer 102 and the metal dielectric liner 100 (if present) to expose the top surface of the ILD 88. After the planarization process, top surfaces of the dielectric layer 102, the metal dielectric liner 100, and the ILD 88 are substantially level or coplanar within process variations of the planarization process. In some embodiments, the planarization process may comprise a CMP process, an etch back process, a grinding process, a combination thereof, or the like. After the planarization process, the dielectric layer 102 has a thickness of between about 10 nm and about 100 nm. In some embodiments (not specifically illustrated), the dielectric layer 102 may be a multi-layer dielectric comprising a nitride and an oxide. In such embodiments, after performing the planarization process, a topmost layer is silicon nitride.

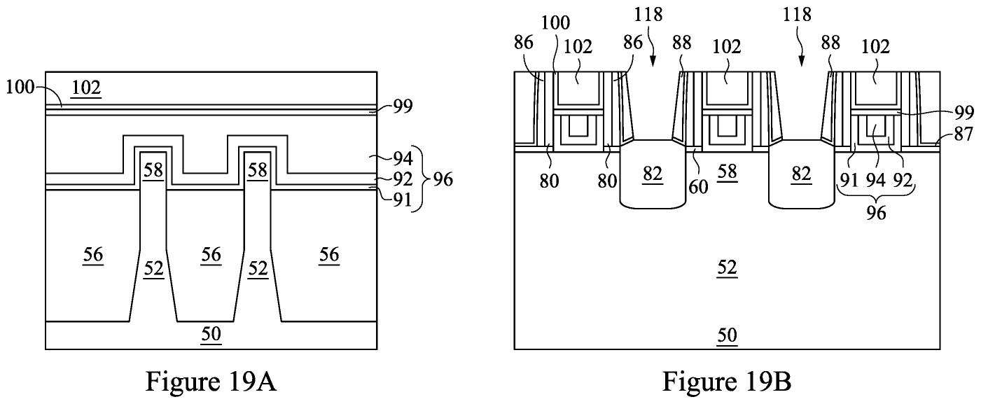

FIGS. 19A and 19B illustrate a patterning process of the ILD 88 and the CESL 87 to form openings 118. The openings 118 expose top surfaces of respective epitaxial source/drain regions 82. In some embodiments, the patterning process may comprise one or more suitable etch processes while using the patterned mask stack as an etch mask. The one or more etch processes may comprise one or more dry etch processes, or the like. The etch processes may be anisotropic. In some embodiments, the one or more etch processes may be performed using etchants, such as CF₄, CHF₃, CH₂F₂, C₄F₆, C₄F₈, Ar, O₂, N₂, H₂, a combination thereof, or the like.

In some embodiments, after forming the openings 118, a remaining portion of the patterned mask stack is removed using, for example, a suitable etch process that is selective to the remaining materials of the patterned mask stack. In some embodiments, the etch process comprises a dry etch process, a wet etch process, a combination thereof, or the like. In some embodiments, the suitable etch process may be performed using etchants, such as HCl, H₂O₂, a combination thereof, or the like.

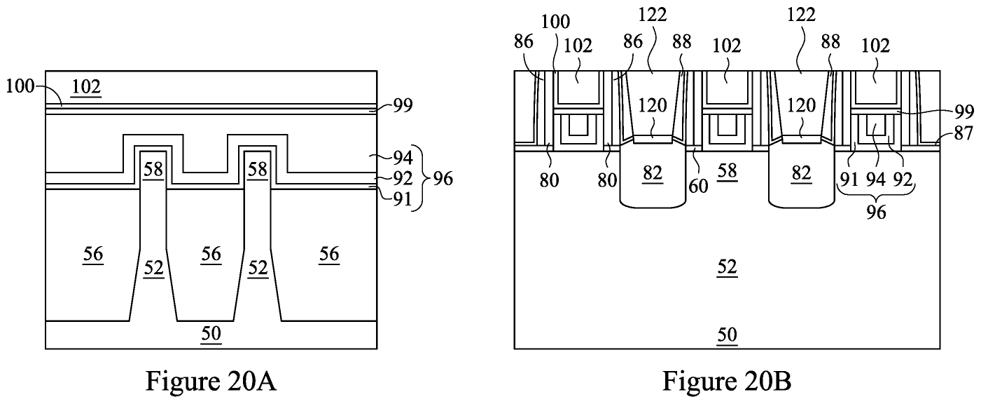

In FIGS. 20A and 20B, after forming the openings 118, silicide layers 120 are formed through the openings 118 over the epitaxial source/drain regions 82. In some embodiments, a metallic material is deposited in the openings 118. The metallic material may comprise Ti, Co, Ni, NiCo, Pt, NiPt, Ir, PtIr, Er, Yb, Pd, Rh, Nb, a combination thereof, or the like, and may be formed using PVD, sputtering, a combination thereof, or the like. Subsequently, an annealing process is performed to form the silicide layers 120. In some embodiments where the epitaxial source/drain regions 82 comprise silicon, the annealing process causes the metallic material to react with silicon to form a silicide of the metallic material at interfaces between the metallic material and the epitaxial source/drain regions 82. After forming the silicide layers 120, unreacted portions of the metallic material may optionally be removed using a suitable removal process, such as a suitable etch process, for example.

After forming the silicide layers 120, conductive features 122 are formed in the openings 118. The conductive features 122 provide electrical connections to respective epitaxial source/drain regions 82. In some embodiments, the conductive features 122 are formed by first forming a barrier layer (not individually shown) in the openings 118. The barrier layer may extend along a bottom and sidewalls of the openings 118. The barrier layer may comprise titanium, titanium nitride, tantalum, tantalum nitride, a combination thereof, a multilayer thereof, or the like, and may be formed by ALD, CVD, PVD, sputtering, a combination thereof, or the like.

Subsequently, an adhesion layer (not specifically illustrated) is formed over the barrier layer within the openings 118. The adhesion layer may comprise cobalt, ruthenium, an alloy thereof, a combination thereof, a multilayer thereof, or the like, and may be formed by ALD, CVD, PVD, sputtering, a combination thereof, or the like. After forming the adhesion layer, a seed layer (not individually shown) is formed over the adhesion layer within the openings 118. The seed layer may comprise copper, titanium, nickel, gold, manganese, a combination thereof, a multilayer thereof, or the like, and may be formed by ALD, CVD, PVD, sputtering, a combination thereof, or the like. Subsequently, a conductive fill material (not individually shown) is formed over the seed layer within the openings 118. In some embodiments, the conductive fill material overfills the openings 118. The conductive fill material may comprise copper, aluminum, tungsten, ruthenium, cobalt, combinations thereof, alloys thereof, multilayers thereof, or the like, and may be formed using, for example, by plating, ALD, CVD, PVD, or other suitable methods.

Still referring to FIGS. 20A and 20B, after forming the conductive fill material, a planarization process is performed to remove portions of the barrier layer, the adhesion layer, the seed layer, and the conductive fill material overfilling the openings 118 and disposed over the dielectric layer 102. Remaining portions of the barrier layer, the adhesion layer, the seed layer, and the conductive fill material form the conductive features 122 in the openings 118. The planarization process may comprise a CMP process, an etch back process, a grinding process, combinations thereof, or the like. After performing the planarization process, top surfaces of the conductive features 122 and a top surface of the dielectric layer 102 are substantially level or coplanar within process variations of the planarization process.

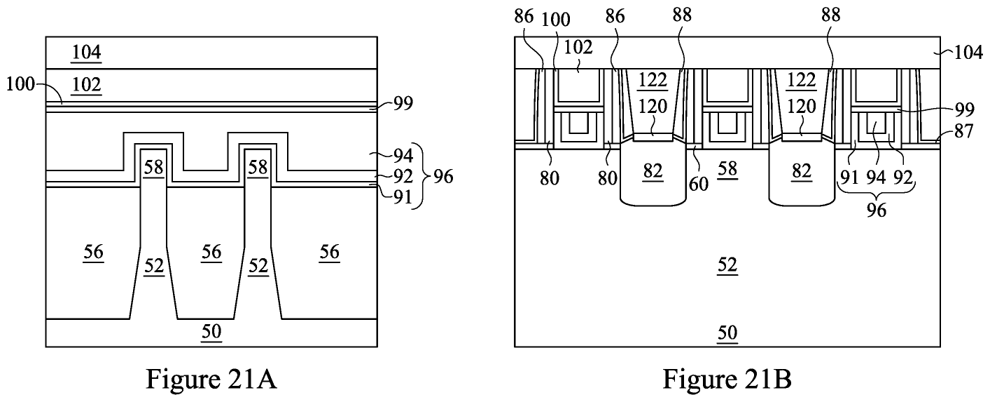

In FIGS. 21A and 21B, a dielectric layer 104 is formed over the dielectric layer 102 and the ILD 88. In some embodiments, the dielectric layer 104 comprises materials that do not include oxygen. For example, the dielectric layer 104 may be formed using similar materials and methods as the dielectric layer 102. In some embodiments, the dielectric layer 102 and the dielectric layer 104 comprise different materials. For example, the dielectric layer 102 (e.g., the topmost layer of the dielectric layer 102 if multi-layered) may be silicon nitride, and the dielectric layer 104 may be silicon carbonitride (SiCN). In addition, in some embodiments, the dielectric layer 104 may include oxygen. For example, the dielectric layer 102 may be any of the materials described above, and the dielectric layer 104 may be an oxide, carbonate, or carbide, such as silicon carbonate (SiCO) or silicon oxycarbide (SiOC). In the various embodiments, the dielectric layer 104 has a high etch selectivity with various adjacent features, such as the dielectric layer 102, the CESL 87, the gate spacers 86, and the gate seal spacers 80. For example, the etch selectivity with a silicon nitride material may be greater than or equal to 10 (e.g., a factor of 10).

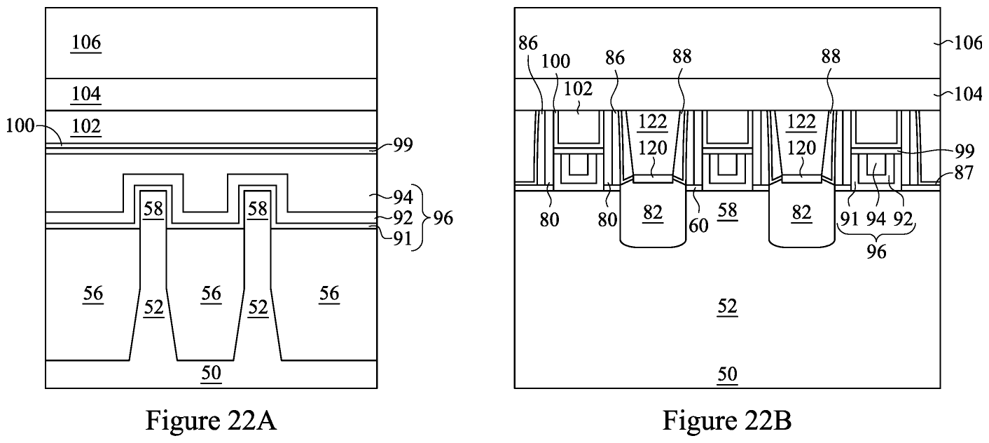

In FIGS. 22A and 22B, an ILD 106 is formed over the dielectric layer 104. In some embodiments, the ILD 106 may be formed using similar materials and methods as the ILD 88 described above with reference to FIGS. 11A and 11B, and the description is not repeated herein. In some embodiments, the ILD 88 and the ILD 106 comprise a same material. In other embodiments, the ILD 88 and the ILD 106 comprise different materials.

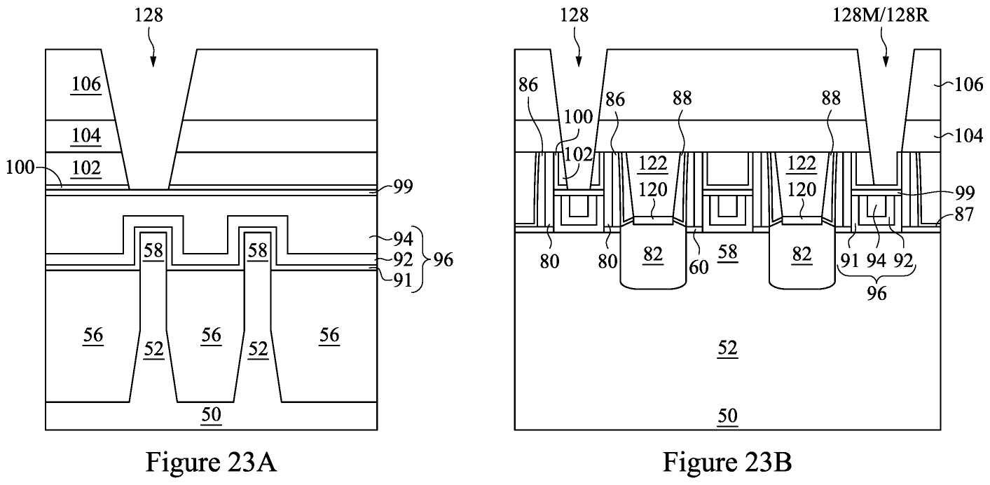

In FIGS. 23A and 23B, openings 128 are formed to expose the gate stacks 96. In a subsequent step, the openings 128 will be filled with a conductive material to form gate contact plugs. In some embodiments, the patterning process comprises suitable photolithography and etch processes and may utilize extreme ultraviolet (EUV) lithography.

As illustrated, the openings 128 extend through the ILD 106, the dielectric layer 104, and the dielectric layer 102. In addition, a last etch process is used to extend the openings 128 through the metal dielectric liner 100 to expose the corresponding gate stacks 96 or the gate contact layer 99 (if present). As such, the metal dielectric liner 100 acts as an etch stop layer to prevent damage to the gate contact layer 99 during the patterning process. In some embodiments, the last etch process is not performed to extend some of the openings 128R. These particular openings 128R may be referred to as redundant openings 128R because they may house redundant conductive features to the gate stacks 96 (e.g., redundant gate contact plugs as discussed in greater detail below).

As further illustrated, some of the openings 128 may be partially misaligned with the corresponding gate stacks 96. These particular openings 128M may be referred to as misaligned openings 128M because they may house misaligned conductive features to the gate stacks 96 (e.g., misaligned gate contact plugs as discussed in greater detail below). The metal dielectric liner 100 protects adjacent features (e.g., the gate seal spacers 80) from being etched when patterning forms the misaligned openings 128M.

In some embodiments, the patterning process is performed by first forming a mask stack (not specifically illustrated) over the ILD 106. The mask may be a multi-layer mask wherein a lower layer is a metal layer that comprises a metal nitride (such as TiN, MON, WN, or the like), a metal carbide (such as WC, WBC, or the like), a boron-containing material (such as BSi, BC, BN, BCN, or the like), a combination thereof, or the like and may be formed using ALD, CVD, a combination thereof, or the like. A middle layer of the mask stack may be a dielectric layer and comprise SiOx, SiN, SiCN, siOC, a combination thereof, or the like, and may be formed using ALD, CVD, a combination thereof, or the like. An upper layer of the mask stack may comprise amorphous silicon (a-Si), a boron-containing material (such as BSi, BC, BN, BCN, or the like), a combination thereof, or the like, and may be formed using ALD, CVD, a combination thereof, or the like. The mask stack is then used to pattern the ILD 106, the dielectric layer 104, and the dielectric layer 102 to form the openings 128 for subsequently formed conductive features that provide electrical connections to the gate stacks 96. The suitable etch processes (including the last etch process) may comprise one or more dry etch processes. The etch process may be anisotropic. In some embodiments, the suitable etch process is performed using etchant, such as CF₄, CHF₃, CH₂F₂, C₄F₆, C₄F₂, Ar, O₂, N₂, H₂, a combination thereof, or the like.

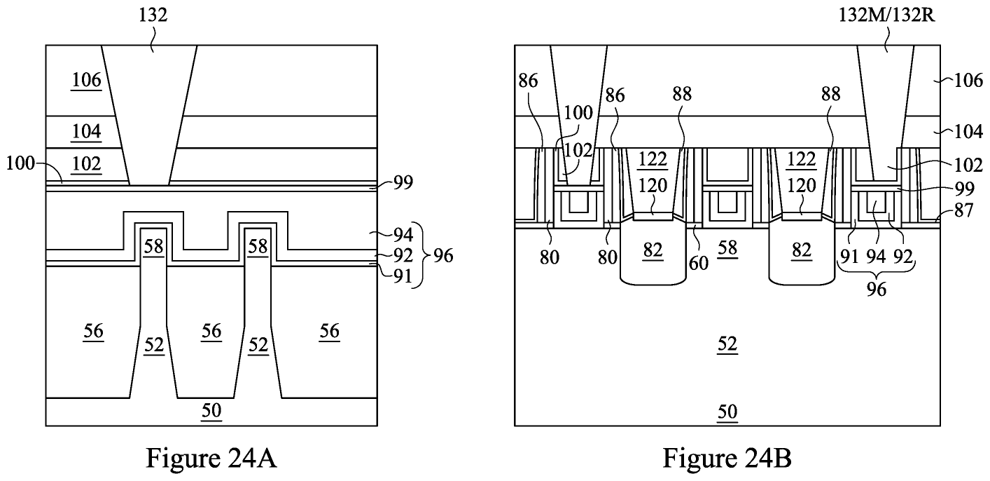

In FIGS. 24A and 24B, conductive features 132 are formed in the openings 128. The conductive features 132 provide electrical connections to respective gate stacks 96. Accordingly, the conductive features 132 may be also referred to as gate contact plugs or gate plugs. In some embodiments, the conductive features 132 may be formed using similar materials and methods as the conductive features 122 described above, and the description is not repeated herein. In some embodiments, the conductive fill material of the conductive features 132 is the same as the conductive fill material of the conductive features 122. In other embodiments, the conductive fill material of the conductive features 132 is different from the conductive fill material of the conductive features 122, such as the conductive features 132 comprising tungsten which may or may not include first forming a barrier layer. For example, the conductive features 132 may be formed of tungsten and deposited using CVD or any suitable method.

After forming the conductive fill material of the conductive features 132, a planarization process is performed to remove portions of the liner layers (e.g., the barrier layer, the adhesion layer, and the seed layer, if present) and the conductive fill material overfilling the openings 128. Remaining portions of the liner layers and the conductive fill material form the conductive features 132 in the openings 128. The planarization process may comprise a CMP process, an etch back process, a grinding process, combinations thereof, or the like. After performing the planarization process, top surfaces of the conductive features 132 and a top surface of the ILD 106 are substantially level or coplanar within process variations of the planarization process.

As discussed above, the conductive features 132 formed in the misaligned openings 128M may be referred to as misaligned conductive features 132M (e.g., misaligned contact gate plugs). In addition, the conductive features 132 formed in the redundant openings 128R may be referred to as redundant conductive features 132R. As illustrated, the redundant conductive features 132R are separated from the gate stacks 96 (e.g., the gate contact layer 99) by the metal dielectric liner 100. The redundant conductive features 132R may not be functional electrical components of the integrated circuit unless later activated after fabrication of the semiconductor device. For example, it may be later determined (e.g., from chip testing of the semiconductor device) that some of the redundant conductive features 132R are needed to be functional electrical components. As such, a high voltage stress (e.g., through a process called eFuse writing) is sent through those redundant conductive features 132R to cause dielectric breakdown of the metal dielectric liner 100 separating the redundant conductive features 132R from the respective gate stacks 96 (e.g., the gate contact layer 99).

In some embodiments, the mask stack may be patterned using suitable etchants for the various layers. In addition, the pattern of the mask stack is then transferred to the ILD 106 and may stop at the dielectric layer 104, which may serve as an etch stop layer. The etch processes may be isotropic, anisotropic, or combinations thereof. For example, the topmost layer of the mask stack (e.g., amorphous silicon) may be dry etched in an anisotropic etch process, and the underlying layers of the mask stack (e.g., the dielectric layer and the metal layer) may be etched in an isotropic etch process to transfer the pattern. An isotropic etch process may then be used to transfer the pattern through the ILD 106. As illustrated, the dielectric layer 104 may be partially etched before the pattern is fully transferred to the ILD 106.

In FIGS. 25A-25G, the ILD 106 is patterned to form openings 126 in the ILD 106. The openings 126 expose respective conductive features 122. In some embodiments, the patterning process comprises suitable photolithography (e.g., utilizing EUV lithography) and etch processes and may include forming a mask stack (not specifically illustrated) similarly as discussed above in connection with the openings 128. The suitable etch process may comprise one or more dry etch processes. The etch process may be anisotropic. In some embodiments, the suitable etch process is performed using etchant, such as CF₄, CHF₃, CH₂F₂, C₄F₆, C₄F₈, Ar, O₂, N₂, H₂, a combination thereof, or the like. As described above in greater detail, the dielectric layers 102 and 104 are formed of different materials and with different etch selectivities. As such, the material of the dielectric layer 104 was chosen such that the dielectric layer 104 acts as an etch stop layer while forming the openings 126. Further, the high etch selectivity ensures that the dielectric layer 102, the CESL 87, and any other exposed silicon nitride layers remain substantially unetched when performing the etch process to extend the openings 126 through the dielectric layer 104. As such, leakage between conductive features that are subsequently formed in the openings 126 and adjacent gate stacks 96 is reduced. In some embodiments, a ratio of an etch rate of the dielectric layer 104 (e.g., comprising SiN) to an etch rate of the dielectric layer 102 (e.g., comprising SiCN or SiCO) for the etch process for forming the openings 126 is about or greater than 10.

FIGS. 25A-25F illustrate a variety of cross-sections as identified in a top-down schematic (e.g., a plan view) provided in FIG. 25G. Note that the structures illustrated in the cross-sections of FIGS. 24A and 24B are continued in FIGS. 25E-25F. However, any of the structures of FIGS. 25A-25F are intended to represent continuations of the exemplary cross-sections of FIGS. 24A and 24B in order to illustrate various embodiment conductive features that will be subsequently formed in the openings 126.

Referring to FIGS. 25A, 25B, and 25G, openings 126A may have rectangular and/or oval shapes (or rounded rectangular shapes) and may be formed directly over respective conductive features 122 (e.g., respective epitaxial source/drain regions 82). In some embodiments, the opening 126A may be centered over the conductive feature 122 or, in the illustrated embodiment, some of the openings 126A may be directly over but laterally shifted (e.g., misaligned) with respect to the underlying conductive feature 122 such that a center axis of the opening 126A is laterally shifted with respect to a center axis of the underlying conductive feature 122. In some embodiments, due to the shift, the opening 126A may extend below the top surface of the underlying conductive feature 122 and extends partially or entirely through the dielectric layer 104 (e.g., exposing the dielectric layer 102). In some embodiments, the opening 126A does not extend below a top surface of the conductive feature 122 due to the dielectric layer 104 acting as an etch stop layer. Moreover, when the openings 126A have a rectangular shape, the openings 126A may have a length and width (e.g., with respect to upper portions of the openings 126A) that are the same or similar and therefore have a square shape. When the openings 126A have an oval shape, the openings 126A may have a major and minor axis that are the same or similar and therefore have a circular shape. For example, the length, width, and/or axis may range from 10 nm to 30 nm, including from 15 nm to 25 nm, such as about 15 nm.

Referring to FIGS. 25A, 25B, and 25G, openings 126B may have a slot shape (e.g., a long rectangular shape) and may be formed over respective conductive features 122 as well as over gate stacks 96. As illustrated, the opening 126B extends beyond lateral edges of the underlying conductive feature 122. As such, the opening 126B may extend below the top surface of the underlying conductive feature 122 and extends partially or entirely through the dielectric layer 104. In addition, because portions of the opening 126B may be directly over proximal gate stacks 96, the openings 126B may expose the dielectric layer 102. In some embodiments, the opening 126B does not extend below a top surface of the conductive feature 122 due to the dielectric layer 104 acting as an etch stop layer. Moreover, a length of the opening 126B may be greater than or equal to two times a width of the opening 126B (e.g., with respect to upper portions of the openings 126B). In some embodiments, the length of the opening 126B may be up to three times the width of the opening 126B. For example, the width of the opening 126B may be the same as for the opening 126A, such as ranging from 10 nm to 20 nm (e.g., about 15 nm), and the length of the opening 126B may range from 30 nm to 60 nm (e.g., about 45 nm).

Referring to FIGS. 25C, 25D, and 25G, openings 126C may have a slot shape (e.g., a long rectangular shape) and may be formed over multiple conductive features 122, such as over two conductive features 122. In some embodiments (not specifically illustrated), the openings 126C may also be formed over gate stacks 96 similarly as discussed with respect to the openings 126B. As illustrated, the opening 126C extends beyond lateral edges of the underlying conductive features 122. As such, the opening 126C may extend below the top surfaces of the underlying conductive features 122 and extends partially or entirely through the dielectric layer 104. In addition, portions of the opening 126C may expose the dielectric layer 102. In some embodiments, the opening 126C does not extend below a top surface of the conductive features 122 due to the dielectric layer 104 acting as an etch stop layer. Moreover, a length and width of the openings 126C (e.g., with respect to upper portions of the openings 126C) may have similar dimensions and proportions as described above in connection with the openings 126B.

Referring to FIGS. 25E, 25F, and 25G, openings 126D may have a slot shape (e.g., a long rectangular shape) and may be formed over respective conductive features 122 to subsequently form butted contacts as discussed in greater detail below. As illustrated, the opening 126D extends beyond lateral edges of the underlying conductive feature 122. As such, the opening 126D may extend below the top surface of the underlying conductive feature 122 and extends partially or entirely through the dielectric layer 104. In addition, portions of the opening 126D may expose the dielectric layer 102. In some embodiments, the opening 126D does not extend below a top surface of the conductive feature 122 due to the dielectric layer 104 acting as an etch stop layer. Moreover, a length and width of the openings 126D (e.g., with respect to upper portions of the openings 126D) may have similar dimensions and proportions as described above in connection with the openings 126B, 126C. As further illustrated, because some of the conductive features 132D are exposed during the process of forming the openings 126D, the patterning process may etch a portion of the conductive features 132D. As a result, the conductive features 132D may be recessed from a top surface of the ILD 106.

In FIGS. 26A-26I, conductive features 130 are formed in the openings 126. The conductive features 130 provide electrical connections to respective epitaxial source/drain regions 82 through the conductive features 122 (and in some cases to some of the gate stacks 96 through the conductive features 132). Accordingly, a combination of a conductive feature 130 and a respective conductive feature 122 may be also referred to as a source/drain contact plug or a source/drain plug. In addition the conductive feature 122 may be referred to as a lower plug, and the conductive feature 130 may be referred to as an upper plug. As illustrated, conductive features 130A are formed in the openings 126A, conductive features 130B are formed in the openings 126B, conductive features 130C are formed in the openings 126C, and conductive features 130D are formed in the openings 126D.

In some embodiments, the openings 126 are formed after forming the conductive features 132. In such embodiments, the conductive features 132 may be protected by, for example, a mask while forming the openings 128 (e.g., similar to the mask stack described above with patterning to form that openings 128 in connection with FIGS. 23A and 23B). In other embodiments, the openings 126 are formed before forming the openings 128. In such embodiments, the conductive features 130 are protected by, for example, a mask while forming the openings 126. In addition, in some embodiments (not specifically illustrated), the openings 126A, 126B, 126C and the respective conductive features 130A, 130B, 130C are formed before the openings 126D and the conductive features 130D. Further, any of the conductive features 130A, 130B, 130C may also be formed separately and in any suitable order.

After forming the conductive fill material of the conductive features 130, a planarization process is performed to remove portions of the liner layers (e.g., the barrier layer, the adhesion layer, and the seed layer, if present) and the conductive fill material overfilling the openings 126. Remaining portions of the liner layers and the conductive fill material form the conductive features 130 in the openings 126. The planarization process may comprise a CMP process, an etch back process, a grinding process, combinations thereof, or the like. After performing the planarization process, top surfaces of the conductive features 130 and the ILD 106 are substantially level or coplanar within process variations of the planarization process.

In some embodiments, the conductive features 130 and 132 may be formed using similar materials and methods as the conductive features 122 described above, and the description is not repeated herein. In some embodiments, a conductive fill material of the conductive features 130 is same as a conductive fill material of the conductive features 132. In other embodiments, the conductive fill material of the conductive features 130 is different from the conductive fill material of the conductive features 132. In some embodiments, the conductive fill material of the conductive features 130 and the conductive fill material of the conductive features 132 are same as the conductive fill material of the conductive features 122. In other embodiments, the conductive fill material of the conductive features 130 and the conductive fill material of the conductive features 132 are different from the conductive fill material of the conductive features 122. In some embodiments, top surfaces of the conductive features 130 and 132, and a top surface of the ILD 106 are substantially level or coplanar.

Referring to FIGS. 26A, 26B, and 26G, the conductive features 130A may have the same rectangular or oval shape as described above in connection with the openings 126A. In addition, the conductive features 130A may be centered over the conductive features 122 or laterally shifted. Moreover, the conductive features 130A may have the dimensions and proportions as described above in connection with the openings 126A. FIG. 26H illustrates how electrical resistance between the conductive features 130 and the conductive features 122 may be affected by the interface area between their respective conductive fill materials. In addition, the liner layers of either of the conductive features 130, 122 may have a higher electrical resistance with the counterparts. For example, the slot shapes of the conductive features 130B reduce this electric resistance by preventing misalignment between the conductive features 130B and the conductive features 122. The electrical resistance is further reduced by increasing the interface area of the respective conductive fill materials of the conductive features 130B, 122. As a result, interfaces of the conductive features 130A, 122 may have a resistance of between 125 ohms and 150 ohms, such as 140 ohms, whereas interfaces of the conductive features 130B, 122 may have a resistance of between 40 ohms and 50 ohms, such as 50 ohms. In some embodiments, interfaces of the conductive features 130B, 122 may have about three or more times less resistance than the resistance between the conductive features 130A, 122.

Referring to FIGS. 26A-26D, 26G, and 26I, the conductive features 130B, 130C may have the same slot shapes as described above in connection with the respective openings 126B, 126C. In addition, the conductive features 130B, 130C may extend laterally beyond the respective conductive features 122 as illustrated and discussed above. Moreover, the conductive features 130B, 130C may have the dimensions and proportions as described above in connection with the openings 126B, 126C. As discussed above, this slot shape allows for a greater interface area of low-resistance electrical connection between the conductive features 130B, 130C and the respective conductive features 122. In particular, the respective conductive fill materials have lower resistance than the respective liner layers. As illustrated in FIG. 26I, the slot shapes provide an increase in the interface area between the conductive fill material of the conductive features 130B, 130C and the conductive fill material of the conductive features 122. As a result, interfaces of the conductive features 130C, 122 may have about three or more times less resistance than the resistance between the conductive features 130A, 122. For example, the resistance between the conductive features 130C, 122 may be between 40 ohms and 50 ohms, such as 46 ohms. An additional advantage of these embodiments (e.g., the slot shapes of the conductive features 130B, 130C) is attaining a ring oscillator boost of up to about 1%.

Referring to FIGS. 26E, 26F, and 26G, the conductive features 130D may have the same slot shape and butted contact configuration as described above in connection with the openings 126D. The conductive features 130D may therefore be referred to as butted contacts because they may contact both the respective conductive feature 132D and respective conductive feature 122. In addition, the conductive features 130D may extend laterally beyond the respective conductive features 122, which achieves the benefits discussed above in conjunction with allowing the butted contact configuration with the conductive features 132. Moreover, the conductive features 130D may have the dimensions and proportions as described above in connection with the openings 126D. It should be further appreciated that the slot shape and butted contact configuration of the conductive features 130D provides similar decreases in electrical resistance as discussed above in connection with the conductive features 130B, 130C. It should be appreciated that the conductive features 130D may be utilized with transistors that are formed in static-RAM (e.g., SRAM) layouts.

In some embodiments (not specifically illustrated), after forming the conductive features 130, additional conductive features may be formed through the ILD 106, the dielectric layer 104, the dielectric layer 102, and the metal dielectric liner 100 to form electrical connections to one of the gate stacks 96 and one of the conductive features 122 (e.g., connected to an underlying epitaxial source/drain region 82). The process may be performed similarly as described above in connection with the conductive features 122, 130, 132, including similar photolithography steps (e.g., utilizing EUV lithography). However, an additional advantage of the conductive features 130D (e.g., the butted contacts) is that they may serve as substitutes for these additional conductive features. As a result, formation of the conductive features 130D eliminates a photolithography step, thereby reducing costs and increasing efficiency and yield of the semiconductor devices.

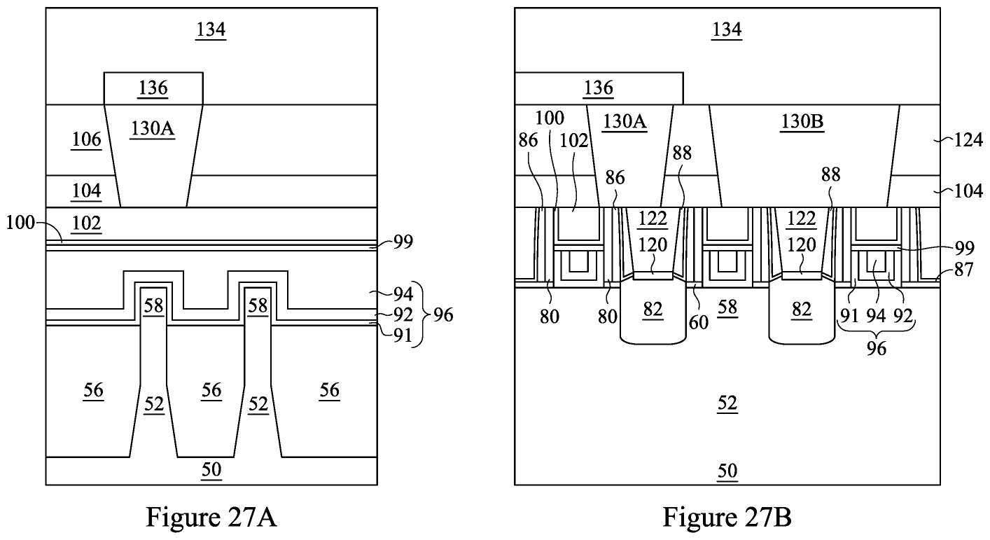

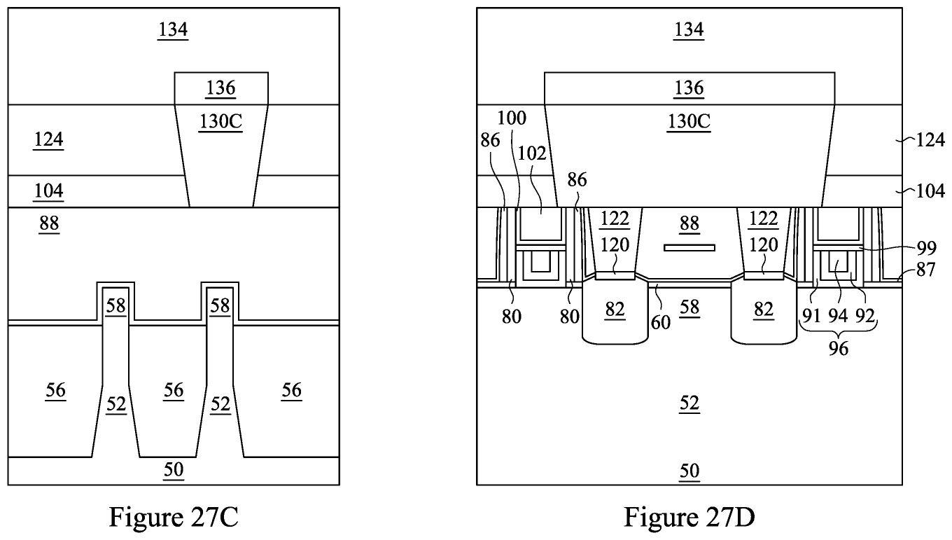

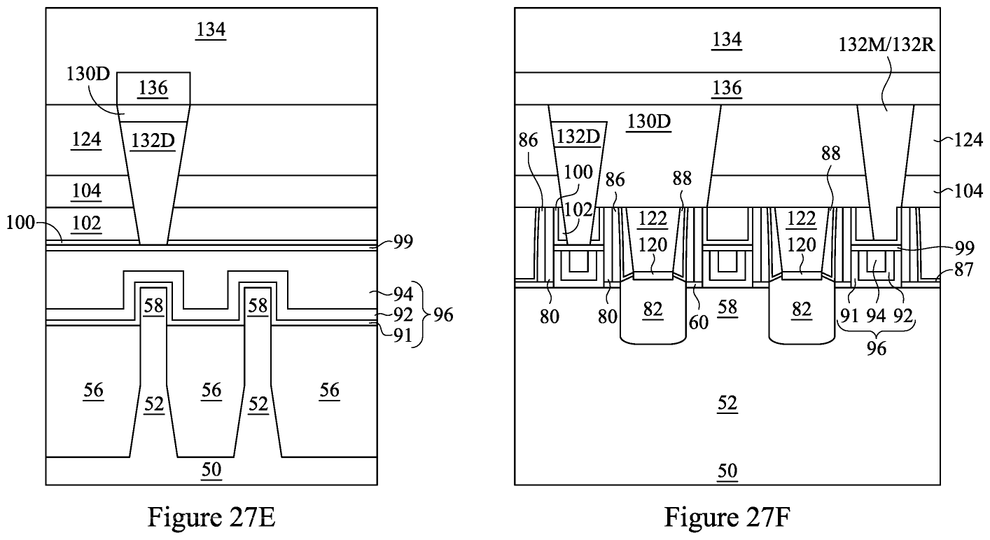

In FIGS. 27A-27F, in some embodiments, an interconnect structure 134 is formed over the conductive features 130 and 132, and the ILD 106. In some embodiments, the interconnect structure 134 comprises a plurality of dielectric layers such as inter-metal dielectrics (IMDs) (not individually illustrated) and conductive features (not individually illustrated) within the IMDs. The IMDs may be formed using similar materials and methods as the ILD 88 described above with reference to FIGS. 11A and 11B, and the description is not repeated herein. The conductive features comprise conductive lines and conductive vias, and may be formed using a single damascene method, a dual damascene method, a combination thereof, or the like. The conductive features of the interconnect structure 134 are in electrical contact with the conductive features 130 and 132.

As further illustrated, the interconnect structure 134 may include a metallization layer 136 which is a lowermost metallization layer in physical contact with some of the conductive features 130, 132. In some embodiments, the metallization layer 136 may include one or more power rails 136P providing power to various underlying devices. For example, some power rails of the metallization layer 136 may extend a greater length than underlying conductive features 130. In addition, as illustrated in FIG. 27D) some of the underlying conductive features 130 may extend a same length as the power rail 136P. Further, respective widths of the conductive features 130 and the metallization layer 136 may be substantially the same. As such, certain conductive features (e.g., the conductive feature 130D) may be considered part of the overlying power rail 136P. However, in some embodiments, the conductive features 130 may comprise tungsten while the power rail 136P comprises copper, or they may comprise substantially the same materials.

Embodiments may achieve advantages. In some embodiments, source/drain contact plugs may be formed in a variety of arrangements to reduce electrical resistance between components, such as a lower plug (e.g., conductive features 122) and an upper plug (e.g., conductive features 130). In particular, the conductive features 130 may have a slot shape in order to prevent misalignment and to increase the surface area of the interface between respective conductive fill materials of the conductive feature 130 and the conductive feature 122, thereby reducing electrical resistance there-between. In addition, the conductive features 130 may extend over other integrated circuit components, such as gate stacks 96. As such, in order to prevent leakage between the conductive features 130 and the gate stacks 96, material of a dielectric layer 104 is chosen to have high etch selectivity with a gate mask (e.g., the dielectric layer 102). Moreover, the metal dielectric liner 100 reduces misalignment risk from formation of the conductive features 132M to the gate stacks 96 while also or alternatively providing versatility with redundant conductive features 132R.

In an embodiment, a method includes: forming an epitaxial source/drain region in a substrate; forming a first inter-layer dielectric over the epitaxial source/drain region; forming a gate stack over the substrate and adjacent to the first inter-layer dielectric; forming a gate mask over the gate stack; forming a source/drain plug through the first inter-layer dielectric and electrically connected to the epitaxial source/drain region; depositing a dielectric layer over the gate mask and the first inter-layer dielectric, the dielectric layer having a different etch selectivity than the gate mask; forming a second inter-layer dielectric over the dielectric layer; etching an opening through the second inter-layer dielectric and the dielectric layer, the opening exposing the source/drain plug and the gate mask; and forming a conductive feature in the opening, the conductive feature being electrically connected to the source/drain plug. In another embodiment, forming the gate mask includes: recessing the gate stack; depositing a metal dielectric liner over the gate stack; and depositing a nitride layer over the metal dielectric liner. In another embodiment, the method further includes: forming an additional epitaxial source/drain region in the substrate; and forming an additional source/drain plug through the first inter-layer dielectric and electrically connected to the additional epitaxial source/drain region, wherein the conductive feature is in physical contact with the source/drain plug and the additional source/drain plug. In another embodiment, the method further includes forming a gate plug through the second inter-layer dielectric and electrically connected to the gate stack, wherein forming the conductive feature comprises forming the conductive feature as a butted contact with the gate plug and the source/drain plug. In another embodiment, the method further includes, before forming the conductive feature, performing an etch process to etch through the second inter-layer dielectric and the dielectric layer, wherein the dielectric layer acts as an etch stop layer during the etch process. In another embodiment, after performing the etch process the gate mask remains substantially unetched. In another embodiment, the dielectric layer and the gate mask may have an etch selectivity greater than or equal to 10. In another embodiment, the gate mask comprises silicon nitride, and wherein the dielectric layer comprises silicon carbonate or silicon carbonitride.

In an embodiment, a method includes: forming a first epitaxial region and a second epitaxial region in a substrate; forming a first oxide layer over the first epitaxial region and the second epitaxial region; forming a first gate stack and a second gate stack over the substrate, the first gate stack being interposed between the first epitaxial region and the second epitaxial region; forming a nitride mask over the first gate stack; etching the first oxide layer to expose the first epitaxial region and the second epitaxial region; forming a first conductive feature over the first epitaxial region and a second conductive feature over the second epitaxial region; forming an etch stop layer over the nitride mask and the first oxide layer; forming a second oxide layer over the etch stop layer; forming a gate plug over and physically contacting the first gate stack; and forming a third conductive feature through the second oxide layer and the etch stop layer, the third conductive feature physically contacting the first conductive feature. In another embodiment, the etch stop layer has an etch selectivity of 10 or greater in comparison with the nitride mask. In another embodiment, in a plan view the third conductive feature has a rectangular shape, and wherein a length of the rectangular shape is two to three times greater than a width of the rectangular shape. In another embodiment, the third conductive feature is directly over the first epitaxial region, the first gate stack, and the second gate stack. In another embodiment, the third conductive feature is directly over the first epitaxial region and the second epitaxial region. In another embodiment, the third conductive feature is in physical contact with the gate plug.

In an embodiment, a semiconductor device includes: a gate stack over a substrate; a metal dielectric liner over the gate stack; a gate mask over the metal dielectric liner; a first oxide layer over the substrate, a top surface of the first oxide layer being level with a top surface of the gate mask; a dielectric layer over the gate mask and the first oxide layer, the dielectric layer being a different material than the gate mask; a second oxide layer over the dielectric layer; a first conductive feature extending through the first oxide layer, a top surface of the first conductive feature being level with the top surface of the gate mask; and a second conductive feature extending through the second oxide layer and the dielectric layer, the second conductive feature being in physical contact with the first conductive feature. In another embodiment, the gate mask comprises silicon nitride, and wherein the dielectric layer comprises silicon carbonitride. In another embodiment, the gate mask comprises silicon nitride, and wherein the dielectric layer comprises silicon carbonate. In another embodiment, in a plan view the second conductive feature has a length being two to three times greater than a width. In another embodiment, the semiconductor device further includes a third conductive feature extending through the gate mask and physically contacting the gate stack, wherein the second conductive feature forms a butted contact with the third conductive feature. In another embodiment, the second conductive feature is directly over the first conductive feature and directly over the gate stack, and wherein the gate mask is electrically interposed between the second conductive feature and the gate stack.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
forming an epitaxial source/drain region in a substrate;
forming a first inter-layer dielectric over the epitaxial source/drain region;
forming a gate stack over the substrate and adjacent to the first inter-layer dielectric;
forming a gate mask over the gate stack;
forming a source/drain plug through the first inter-layer dielectric and electrically connected to the epitaxial source/drain region;
depositing a dielectric layer over the gate mask and the first inter-layer dielectric, the dielectric layer having a different etch selectivity than the gate mask;
forming a second inter-layer dielectric over the dielectric layer;
etching an opening through the second inter-layer dielectric and the dielectric layer, the opening exposing the source/drain plug and the gate mask; and
forming a conductive feature in the opening, the conductive feature being electrically connected to the source/drain plug.

2. The method of claim 1, wherein forming the gate mask comprises:
recessing the gate stack;
depositing a metal dielectric liner over the gate stack; and
depositing a nitride layer over the metal dielectric liner.

3. The method of claim 1, further comprising:
forming an additional epitaxial source/drain region in the substrate; and
forming an additional source/drain plug through the first inter-layer dielectric and electrically connected to the additional epitaxial source/drain region, wherein the conductive feature is in physical contact with the source/drain plug and the additional source/drain plug.

4. The method of claim 1, further comprising forming a gate plug through the second inter-layer dielectric and electrically connected to the gate stack, wherein forming the conductive feature comprises forming the conductive feature as a butted contact with the gate plug and the source/drain plug.

5. The method of claim 1, further comprising, before forming the conductive feature, performing an etch process to etch through the second inter-layer dielectric and the dielectric layer, wherein the dielectric layer acts as an etch stop layer during the etch process.

6. The method of claim 5, wherein after performing the etch process the gate mask remains substantially unetched.

7. The method of claim 1, wherein the dielectric layer and the gate mask may have an etch selectivity greater than or equal to 10.

8. The method of claim 7, wherein the gate mask comprises silicon nitride, and wherein the dielectric layer comprises silicon carbonate or silicon carbonitride.

9. A method, comprising:
forming a first epitaxial region and a second epitaxial region in a substrate;
forming a first oxide layer over the first epitaxial region and the second epitaxial region;
forming a first gate stack and a second gate stack over the substrate, the first gate stack being interposed between the first epitaxial region and the second epitaxial region;
forming a nitride mask over the first gate stack;
etching the first oxide layer to expose the first epitaxial region and the second epitaxial region;
forming a first conductive feature over the first epitaxial region and a second conductive feature over the second epitaxial region;
forming an etch stop layer over the nitride mask and the first oxide layer;
forming a second oxide layer over the etch stop layer;
forming a gate plug over and physically contacting the first gate stack; and
forming a third conductive feature through the second oxide layer and the etch stop layer, the third conductive feature physically contacting the first conductive feature.

10. The method of claim 9, wherein the etch stop layer has an etch selectivity of 10 or greater in comparison with the nitride mask.

11. The method of claim 9, wherein in a plan view the third conductive feature has a rectangular shape, and wherein a length of the rectangular shape is two to three times greater than a width of the rectangular shape.

12. The method of claim 11, wherein the third conductive feature is directly over the first epitaxial region, the first gate stack, and the second gate stack.

13. The method of claim 11, wherein the third conductive feature is directly over the first epitaxial region and the second epitaxial region.

14. The method of claim 9, wherein the third conductive feature is in physical contact with the gate plug.

15. A semiconductor device, comprising:
a gate stack over a substrate;
a metal dielectric liner over the gate stack;
a gate mask over the metal dielectric liner;
a first oxide layer over the substrate, a top surface of the first oxide layer being level with a top surface of the gate mask;
a dielectric layer over the gate mask and the first oxide layer, the dielectric layer being a different material than the gate mask;
a second oxide layer over the dielectric layer;
a first conductive feature extending through the first oxide layer, a top surface of the first conductive feature being level with the top surface of the gate mask; and
a second conductive feature extending through the second oxide layer and the dielectric layer, the second conductive feature being in physical contact with the first conductive feature.

16. The semiconductor device of claim 15, wherein the gate mask comprises silicon nitride, and wherein the dielectric layer comprises silicon carbonitride.

17. The semiconductor device of claim 15, wherein the gate mask comprises silicon nitride, and wherein the dielectric layer comprises silicon carbonate.

18. The semiconductor device of claim 15, wherein in a plan view the second conductive feature has a length being two to three times greater than a width.

19. The semiconductor device of claim 15, further comprising a third conductive feature extending through the gate mask and physically contacting the gate stack, wherein the second conductive feature forms a butted contact with the third conductive feature.

20. The semiconductor device of claim 15, wherein the second conductive feature is directly over the first conductive feature and directly over the gate stack, and wherein the gate mask is electrically interposed between the second conductive feature and the gate stack.
